(19) United States
(12) Patent Application Publication
(10) Pub. No.: US 2025/0378857 A1
(43) Pub. Date: Dec. 11, 2025

(54) MEMORY DEVICE INCLUDING CONDUCTIVE CONTACTS AND SUPPORT STRUCTURES

(71) Applicant: Micron Technology, Inc., Boise, ID (US)

(72) Inventors: Darwin A. Clampitt, Wilder, ID (US); Martin Jared Barclay, Middleton, ID (US); Sidhartha Gupta, Boise, ID (US); Brittany Kohoutek, Boise, ID (US); Jiewei Chen, Meridian, ID (US)

(21) Appl. No.: 19/219,155

(22) Filed: May 27, 2025

Related U.S. Application Data
(60) Provisional application No. 63/658,266, filed on Jun. 10, 2024.

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

Some embodiments include apparatuses and methods of forming the apparatuses. One of the apparatuses includes a memory device, which includes: a first region including first levels of conductive materials interleaved with first levels of dielectric materials, and first memory cells including pillars extending through at least a portion of the first levels of conductive materials and first levels of dielectric materials; a second region including second levels of conductive materials interleaved with second levels of dielectric materials, and second memory cells including pillars extending through at least a portion of the first levels of conductive materials and first levels of dielectric materials; a third region including a dielectric structure separating the first levels of conductive materials from the second levels of conductive materials; and a conductive contact extending through at least a portion of the third region and contacting a conductive material of the first levels of conductive materials.

### PRIORITY APPLICATION

This application claims the benefit of priority to U.S. Provisional Application Ser. No. 63/658,266, filed Jun. 10, 2024, which is incorporated herein by reference in its entirety.

### BACKGROUND

Dimensions of structures of some of the components in a memory device (e.g., a flash memory device) are relatively small (e.g., in nanometer size). At a certain small dimension of a memory device, structural damage (e.g., collapse) in part of the memory device may occur during fabrication. Such collapse can negatively affect yield, cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3 shows a detailed schematic diagram of two blocks of the memory device of FIG. 2, according to some embodiments described herein.

FIG. 4 shows a top view of a structure of a portion of the memory device of FIG. 3 including a region of a memory array, a conductive contact region, and structures between the blocks of the memory device, according to some embodiments described herein.

FIG. 5 shows a side view (e.g., cross-section) of a structure of a portion of the memory device of FIG. 4, including tiers of materials that include respective memory cells and control gates associated with the memory cells, according to some embodiments described herein.

FIG. 6 shows a top view of the structure of the memory device of FIG. 4, including a region between the blocks of the memory device and conductive contacts in the region, according to some embodiments described herein.

FIG. 7 shows a diagram representing the structure of the memory device of FIG. 6 showing relative locations of the blocks and the conductive contacts of the memory device, according to some embodiments described herein.

FIG. 8 shows a variation in the connections between conductive contacts and control gates of memory device of FIG. 7, according to some embodiments described herein.

FIG. 9A and FIG. 9B shows more detail of the structure of the conductive contacts of the memory device of FIG. 7, according to some embodiments described herein.

FIG. 10A through FIG. 27C show different views of elements during processes of forming a memory device, according to some embodiments described herein.

FIG. 28 through FIG. 35 show different views of elements during alternative processes of forming a memory device, according to some embodiments described herein.

FIG. 36A and FIG. 36B show a memory device including conductive contacts and control gates located at a region outside memory cell array region, according to some embodiments described herein.

FIG. 37 through FIG. 47 show different views of elements during alternative processes of forming another memory device, according to some embodiments described herein.

### DETAILED DESCRIPTION

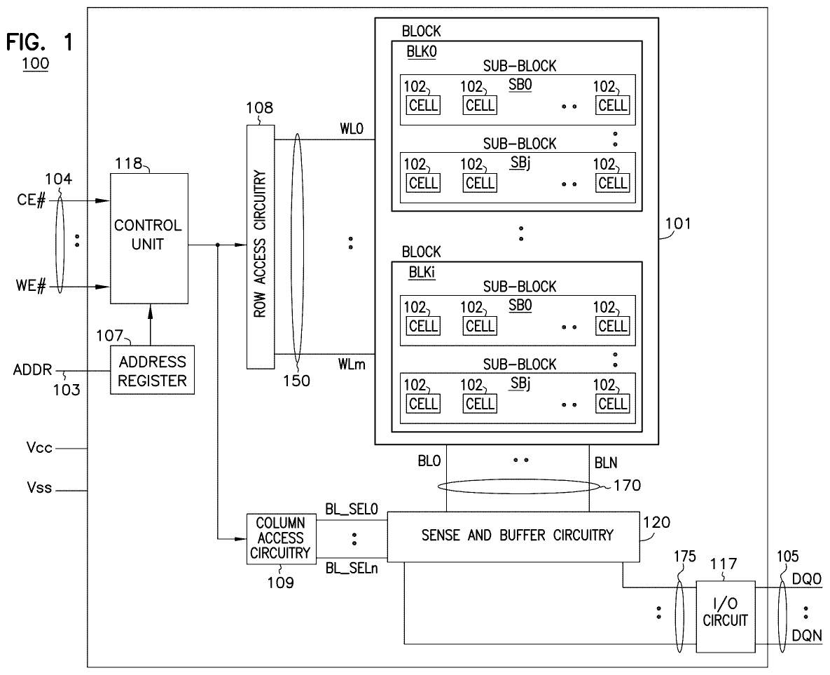

The techniques described herein involve a memory device including memory cells formed in tiers (different physical levels) of the memory device. The tiers include respective levels of conductive materials. The conductive materials form part of control gates (e.g., word lines) associated with the memory cells. The memory device also includes conductive contacts coupled to respective control gates. The conductive contacts and the control gates are part of access lines (e.g., word lines) of the memory device. The memory device also includes support pillars (e.g., dielectric pillars) adjacent the conductive contacts. In an example, the conductive contacts are located between the blocks of the memory device. In another example, the support pillars are located adjacent the conductive contacts. As described in more detail below, the structures and locations of the conductive contacts allow improvement in at least one of yield, cost, performance, and reliability associated with the memory device. Other improvements and benefits of the techniques described herein are further discussed below with reference to FIG. 1 through FIG. 47.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks (memory cell blocks) BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of the memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of the memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

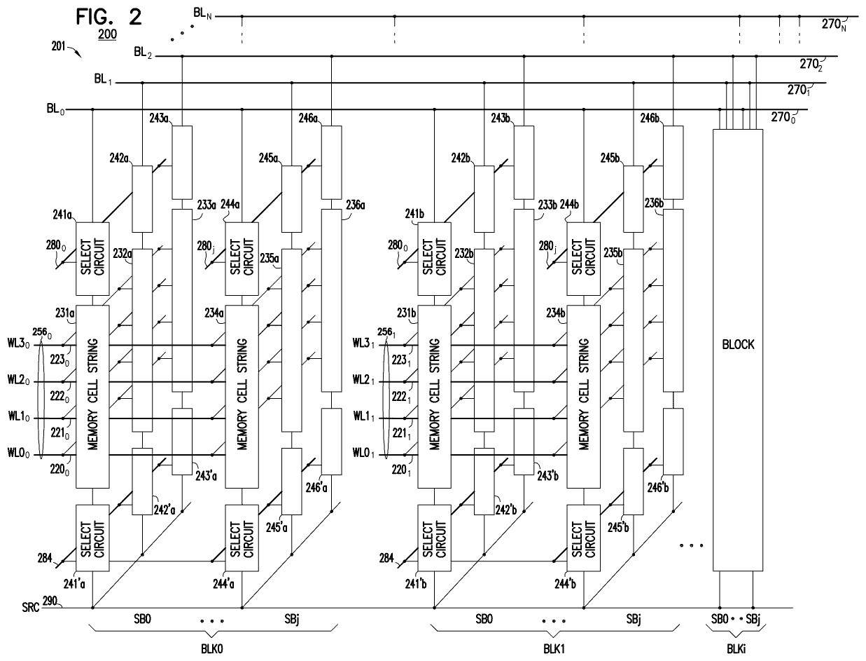

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 27C.

FIG. 2 shows a general schematic diagram of a portion of a memory device 200 including a memory array 201 having blocks (memory cell blocks or blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

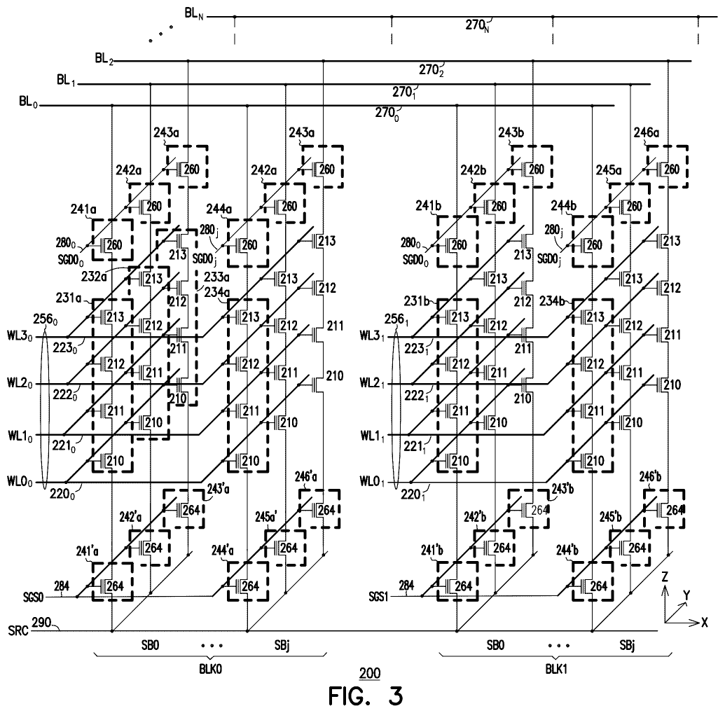

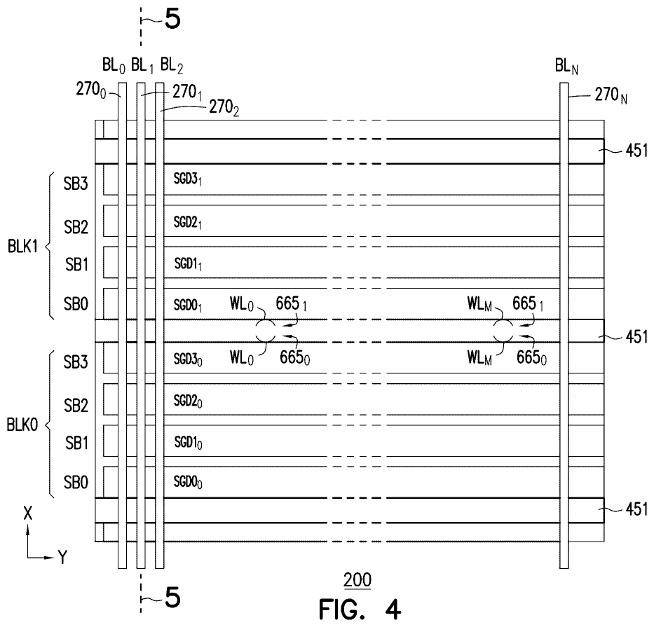

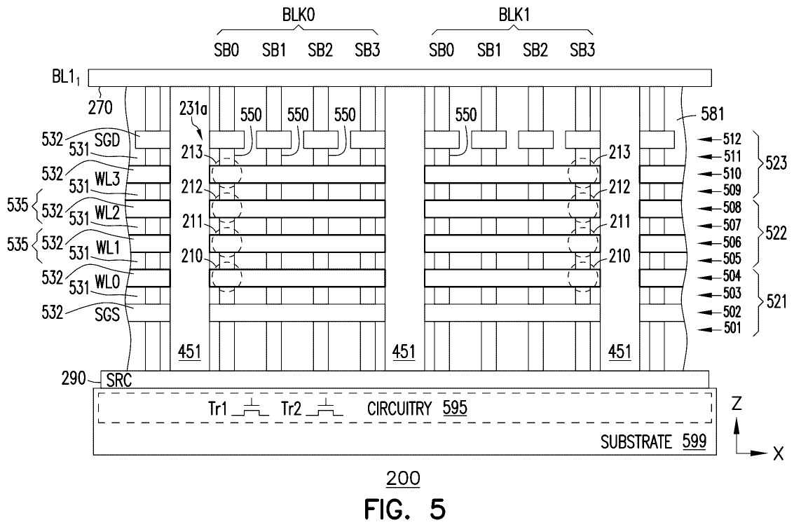

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3 and FIG. 4) and a pillar (e.g., pillar 550 in FIG. 5) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 2702.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of the control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3) coupled between source 290 and a respective memory cell string. The source select gate (e.g., transistor) can be controlled (e.g., turned on or turned off) by a signal on a respective source select line based on a voltage provided to the signal.

FIG. 3 shows a detailed schematic diagram including blocks of the blocks BLK0 and BLK1 of memory device 200 of FIG. 2, according to some embodiments described herein. In FIG. 3, directions X, Y, and Z in FIG. 3 can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3. As shown in FIG. 3, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices described herein are given labels with the same reference number. For example, as shown in FIG. 3, similar drain select lines (and their associated signals) are given the same labels for simplicity. However, as shown in FIG. 3, the drain select lines (from the same block or from different blocks) of memory device 200 are electrically separated from each other and carry different signals (although the signals are given the same labels).

As shown in FIG. 3, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3, each of the memory cell strings (e.g., memory cell string 231a) of memory device 200 can include series-connected memory cells that include one of memory cells 210, one of memory cells 211, one of memory cells 212, and one of memory cells 213. FIG. 3 shows an example of four memory cells 210, 211, 212, and 213 in each memory cell string. The number of memory cells in each memory cell string can vary. For example, each memory string can include up to hundreds (or more) of memory cells.

As shown in FIG. 3, each drain select circuit (e.g., select circuit 241a) can include one of select gates 260. Each source select circuit (e.g., select circuit 241′a) can include one of select gates 264.

Each select gate 260 in FIG. 3 can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

FIG. 3 shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 4 shows a top view of a structure of a portion of memory device 200 of FIG. 2 and FIG. 3 including blocks BLK0 and BLK1, and dielectric structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3 are also not repeated.

In FIG. 4, dielectric structures 451 can be formed to separate (physically separate) one block and another block of memory device 200. Two adjacent blocks (e.g., blocks BLK0 and BLK1) can be separated from each other by one of the structures 451. Adjacent blocks can be located immediately next to each other.

Each dielectric structure 451 can have a length in the Y-direction. Each dielectric structure 451 can include a dielectric material (e.g., silicon dioxide) or a combination of a dielectric material and additional material (e.g., a non-conductive material). Each dielectric structure 451 can include a slit (not labeled) and materials (not labeled) formed in (e.g., filled in) the slit. The slit can include (or can be part of) a trench between adjacent blocks (e.g., blocks BLK0 and BLK1). Dielectric structure 451 can be called a dielectric structure or a slit structure. The regions of memory device 200 at which structures 451 are located can be called slit regions.

As shown in FIG. 4, data lines 270₀ through 270_{N} can extend across the blocks (e.g., blocks BL0 and BL1) in the X-direction. Data lines 270₀ through 270_{N} can be located over and in electrical contact with pillars (e.g., pillars 550 of FIG. 5) of memory device 200. Connections (e.g., vertical connections in the Z-direction) between pillars 550 and data lines 270₀ through 270_{N} may be hidden under data lines and are not shown in FIG. 4. However, each pillar in the same sub-block of a block can be coupled to a separate (e.g., unique) data line among data lines 270₀ through 270_{N}.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include control gates associated with signals WL₀ through WL_{M} (which represent the control gates associated with signals WL0₁, WL1₁, WL2₁, and WL3₁ in FIG. 3), select line (e.g., source select line) associated with signal SGS1 (also shown in FIG. 3), sub-blocks SB0, SB1, SB2, and SB3, select lines (e.g., drain select lines) SGD01, SGD11, SGD21, and SGD31.

In FIG. 4, the control gates associated with signals WL₀ through WL_{M} in block BLK0 represent the control gates associated with signals WL0₀, WL1₀, WL2₀, and WL3₀ in FIG. 3. In FIG. 4, the control gates associated with signals WL₀ through WL_{M} in block BLK0 represent the control gates associated with signals WL0₁, WL1₁, WL2₁, and WL3₁ in FIG. 3. As shown in FIG. 4, structure 451 between block BLK0 and BLK1 separates (physically and electrically separates) the control gates associated with signals WL₀ through WL_{M} in block BLK0 from control gates associated with signals WL₀ through WL_{M} in block BLK1.

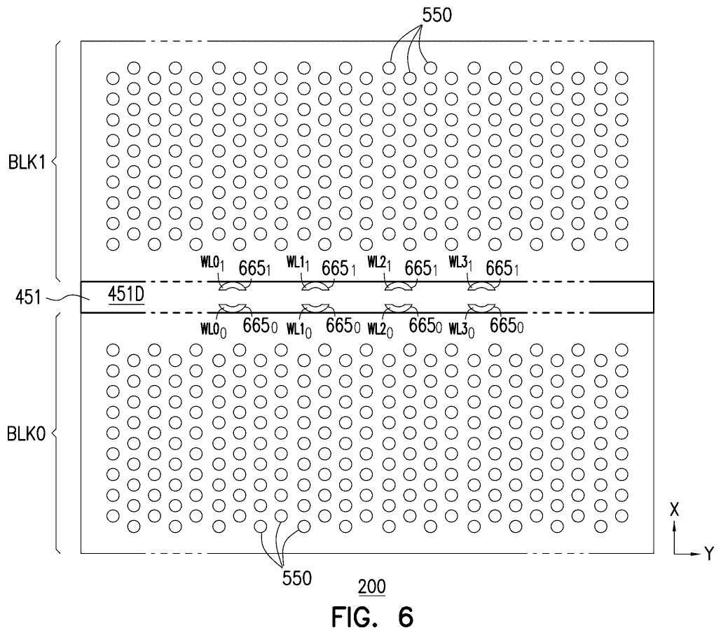

Memory device 200 can include conductive contacts (e.g., word line contacts) 665₀ and 665₁ located between blocks BLK0 and BLK1 in the region at which dielectric structure 451 is located. Detailed description of conductive contacts 665₀ and 665₁ are described below reference to FIG. 6 through FIG. 9B.

As shown in FIG. 4, conductive contacts 665₀ are associated with (e.g., coupled to) respective control gates of block BLK0). Conductive contacts 665₁ are associated with (e.g., coupled to) respective control gates of block BLK1.

A side view side view (e.g., cross-section) at memory array (memory cell array) 201 of memory device 200 at line 5 in FIG. 4 is shown in FIG. 5.

FIG. 5 shows a side view (e.g., cross-section) of a structure of a portion of memory device 200 of FIG. 4 including tiers (tiers of materials) 535 that include respective memory cells and control gates associated with (e.g., to control) the memory cells, according to some embodiments described herein. FIG. 5 also partially shows other blocks (on the left and right sides of blocks BLK0 and BLK1) of memory device 200.

As shown in FIG. 5, memory device 200 can include a substrate 599 and different levels 501 through 512 of memory device 200 over substrate 599 in the Z-direction. Levels 501 through 512 are physical device levels of memory device 200 over substrate 599. Memory device 200 can include decks 521, 522, and 523. Each of decks 521, 522, and 523 can include part of memory devices 200 in different physical levels (e.g., levels 501 through 512) of memory device 200.

Memory device 200 can include a dielectric material 581 formed over at least a portion of memory device 200. In FIG. 5, memory cells 210, 211, 212, and 213 of the memory cell strings (e.g., memory cell string 231a in FIG. 3) of respective sub-blocks SB0, SB1, SB2, and SB3 of each of blocks BLK0 and BLK1 can be formed over substrate 599 and source 290 (e.g., formed vertically in Z-direction in respective levels among levels 501 through 512).

In FIG. 5, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 4. In another example, in block BLK1, the select line indicated by signal SGS can correspond to the select line (e.g., source select line) associated with signals SGS1 of block BLK1 shown in FIG. 4.

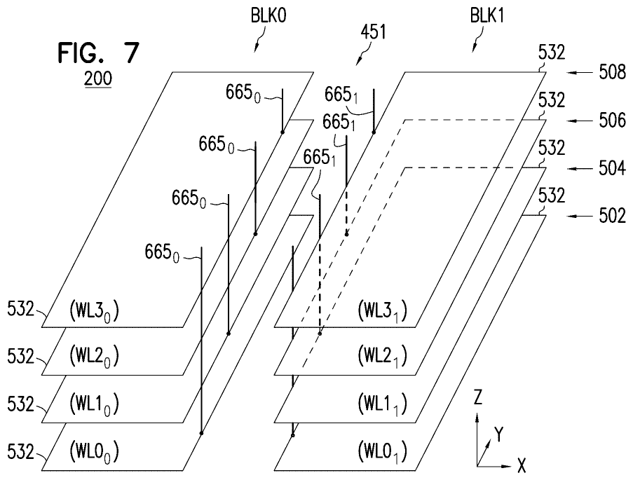

In FIG. 5, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 4. In another example, in block BLK1 in FIG. 5, the control gates indicated by signals WL0, WL1, WL2, and WL3 can correspond to respective control gates associated with signals WL0₁, WL1₁, WL2₁, and WL3₁, respectively, of block BLK1 shown in FIG. 4. FIG. 5 shows memory device 200 includes four control gates (associated with signals WL0, WL1, WL2, and WL3) as an example. However, memory device 200 can include numerous control gates (e.g., control gates associated with signals WL₀ through WL_{M}) as shown in FIG. 7.

As shown in FIG. 5, memory device 200 can include dielectric materials (e.g., silicon dioxide) 531 located on levels 503, 505, 507, 509, and 511. Dielectric materials 531 in a respective block are interleaved with conductive materials 532. Conductive materials 532 can form respective control gates (associated with signals WL0, WL1, WL2, and WL3) in the respective block. As shown in FIG. 5, dielectric materials 531 can be located on respective levels among levels 501 through 512. Conductive materials 532 can be located on respective levels (e.g., levels 502, 504, 506, 508, 510, and 512) among levels 501 through 512 that are interleaved with the levels of dielectric materials 531. Examples of conductive materials 532 (which form the control gates) include a single conductive material (e.g., single metal, e.g., tungsten) or a combination of different layers of conductive materials. For example, each of the control gates of blocks BLK0 and BLK1 can include (e.g., multi-layers of) aluminum oxide, titanium nitride, tungsten.

The levels of dielectric material 531 and the levels of conductive materials 532 can form tiers 535 of memory device 200. Each tier 535 can include a level of dielectric material 531 and a level of conductive material 532. For simplicity, only some of tiers 535 are labeled in FIG. 5. As shown in FIG. 5, tiers 535 can be located one over another and can include respective levels of memory cells 210, 211, 212, and 213, and control gates associated with the memory cells. FIG. 5 shows a few tiers (e.g., four tiers 535) of memory device 200 as an example. However, memory device 200 can include up to hundreds of tiers (or more than hundreds of tiers).

As shown in FIG. 5, memory device 200 can include pillars (memory cell pillars) 550 in blocks BL0 and BLK1. Each of the pillars 550 can be part of a respective memory cell string (e.g., memory cell string 231a). Each of the pillars 550 can have length extending through at least a portion of each of decks 521, 522, and 523 in the Z-direction (e.g., extending vertically from substrate 599) between substrate 599 and data line 270. As shown in FIG. 5, the Z-direction is also a direction at which the length of pillar 550 extends from one tier to another tier, which is also a direction from levels of dielectric materials 531 to levels of conductive materials 532.

As shown in FIG. 5, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5, source 290 can include a conductive material (or materials, e.g., different levels of different materials) and can extend in the X-direction. FIG. 5 shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

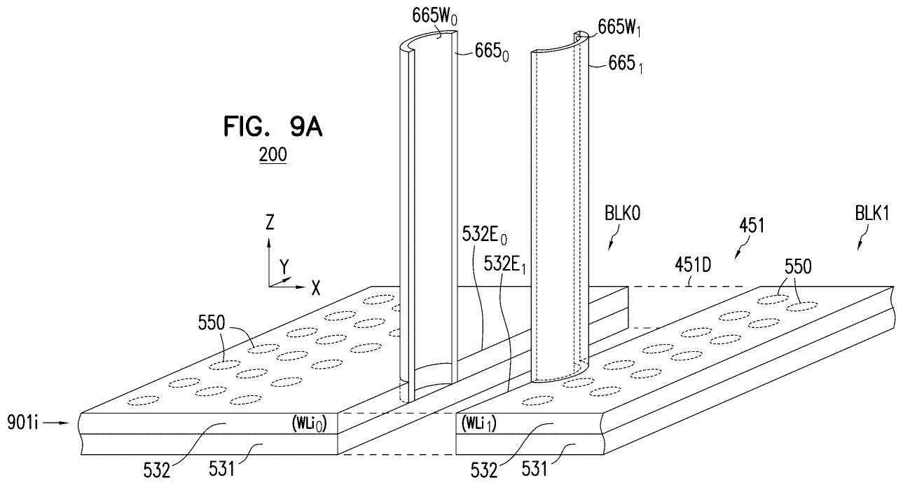

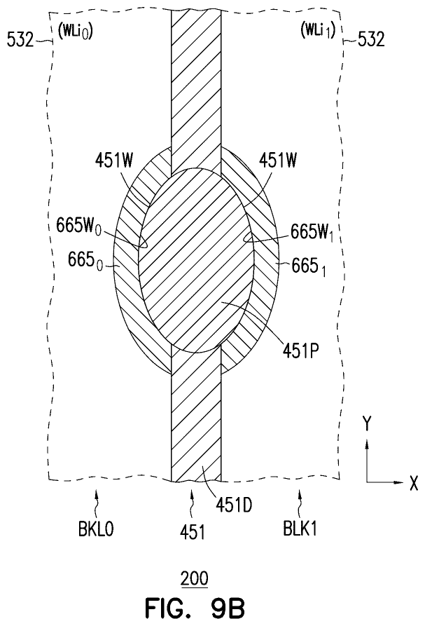

FIG. 6 shows a top view of a structure of memory device 200 of FIG. 4, according to some embodiments described herein. As shown in FIG. 6, pillars 550 (shown in top view) are located in the region that is included in memory array 201. Conductive contacts 665₀ and 665₁ can be located in a region that includes dielectric structure 451 between blocks BLK0 and BLK1. Dielectric structure 451 can include a material (e.g., dielectric material 451D) that separates block BLK0 from block BLK1. The material (or materials) of conductive contacts 665₀ and 665₁ can be similar to or the same as conductive material 532 of FIG. 9A.

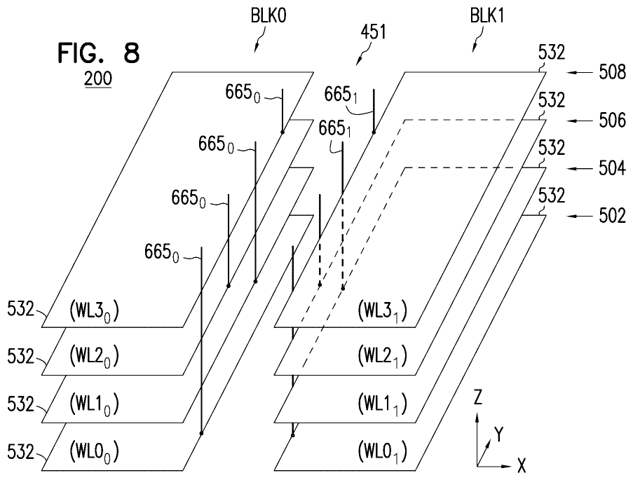

Conductive contacts 665₀ and 665₁ can contact (form an electrical connection with) respective control gates (shown in FIG. 7) associated block BLK0 and block BLK1, respectively, of memory device 200. Conductive contacts 665₀ allow signals (e.g., word line signals WL0₀, WL1₀, WL2₀, and WL3₀) to be provided to respective control gates of block BLK0 through conductive contacts 665₀. Conductive contacts 665₁ allow signals (e.g., word line signals WL0₁, WL1₁, WL2₁, and WL3₁) to be provided to respective control gates of block BLK1 through conductive contacts 665₁. FIG. 7, FIG. 8, FIG. 9A, and FIG. 9B (described in more detail below) show different views of memory device 200 including of conductive contacts 665.

FIG. 7, FIG. 8, FIG. 9A, and FIG. 9B shows different views of memory device 200 including conductive contacts 665₀ and 665₁ and associated control gates, according to some embodiments described herein. FIG. 7 and FIG. 8 show the same view of memory device 200 except for the variation in the connections between conductive contacts and control gates. For simplicity and to improve readability, FIG. 7 and FIG. 8 show simple diagrams representing the structure of memory device 200. Some of the details of FIG. 7 and FIG. 8 are shown in FIG. 9A and FIG. 9B. FIG. 7 and FIG. 8 omit dielectric materials 531 between conductive materials 532. FIG. 9A shows a conductive material 532 and a dielectric conductive material 531 (which can form a tier of memory device 200). Conductive materials 532 can form respective control gates. In block BLK0, the control gates are associated with signals WL0₀, WL1₀, WL2₀, WL3₀ as shown in FIG. 7. In block BLK1, the control gates are associated with signals WL0₁, WL1₁, WL2₁, WL3₁ as shown in FIG. 7. As shown in FIG. 7 and FIG. 8, conductive contacts 665₀ and 665₁ and of blocks BLK0 and BLK1 (which are adjacent blocks) can be located in the region that includes dielectric structure 451.

FIG. 7 and FIG. 8 show different example patterns of the connections between conductive contacts 665₀ and 665₁ associated with control gates of memory device 200. For example, the connections of the pair of conductive contacts 665₀ and 665₁ coupled to respective control gates associated with signals WL2₀ and WL2₁ (in FIG. 7) can be exchanged with the connections of the pair of conductive contacts 665₀ and 665₁ coupled to respective control gates associated with signals WL1₀ and WL1₁ (in FIG. 7), so that the connections of the exchanged pairs become the connections shown in FIG. 8. Memory device 200 can have different connection patterns, as long as different control gates are associated with (coupled to) different conductive contacts. Thus, two different control gates can be associated with two different conductive contacts. Two different control gates may not share a conductive contact (may not have a common conductive contact).

FIG. 9A shows a 3-D view (three-dimensional view) memory device 200 including two conductive contacts 665₀ and 665₁ coupled to two different control gates associated with signals WLi₀ and WLi₁. FIG. 9B shows a top view (e.g., cross-section) of part of memory device 200 of FIG. 9A. As shown in FIG. 9A, dielectric structure 451 can include a length in the Y-direction, which is a direction perpendicular to a direction (e.g., the X-direction) from conductive contact 665₀ to conductive contact 665₁.

As shown in FIG. 9B, dielectric structure 451 can include a dielectric portion 451P between (e.g., directly between) and contacting conductive contacts 665₀ and 665₁). Dielectric portion 451P includes a side wall 451W. For simplicity, dielectric portion 451P is omitted from FIG. 9A.

In FIG. 9A and FIG. 9B, signal WLi₀ represents one of signals WL0₀, WL1₀, WL2₀, WL3₀ in block BLK0 of FIG. 7. Signal WLi₁ represents one of signals WL0₁, WL1₁, WL2₁, WL3₁ in block BLK1 of FIG. 7. Conductive contacts 665₀ and 665₁ represent two conductive contacts 665₀ and 665₁, respectively, of FIG. 7.

As shown in FIG. 9A and FIG. 9B, conductive contacts 665₀ and 665₁ are adjacent each other in the X-direction. Each of conductive contacts 665₀ and 665₁ includes a length in the Z-direction. Level 901i can be one of levels 502, 504, 506, and 508 of FIG. 7 or FIG. 8. Levels 502, 504, 506, and 508 are the same as those shown in FIG. 5. As shown in FIG. 9A, the control gates associated with signals WLi₀ and WLi₁ can be located on the same level among the levels that contain respective conductive materials 532. For example, the control gates associated with signals WLi₀ and WLi₁ can be located on the same level 901i, which can be one of levels 502, 504, 506, and 508 in FIG. 7. Since the control gates associated with signals WLi₀ and WLi₁ can be located on the same level 901i, the conductive contacts (e.g., conductive contacts 665₀ and 665₁) associated with the control gates can have the same length (length in the Z-direction).

As shown in FIG. 9A and FIG. 9B, conductive contacts 665₀ and 665₁ can be located on opposite sides (in the X-direction) of dielectric portion 451P. Conductive contacts 665₀ and 665₁ can include respective side walls 665W₀ and 665W₁ (e.g., vertical side walls in the Z-direction).

As shown in FIG. 9A and FIG. 9B, side wall 665W₀ can be concave into conductive material 532 that forms the control gate associated with signal WLi₀. Side wall 665W₁ can be concave into conductive material 532 that forms the control gate associated with signal WLi₁.

As shown in FIG. 9A and FIG. 9B, each of side walls 665W₀ and 665W₁ has a semi-circular or semi-oval shape (like a shape of letter “C” from top view). Conductive contacts 665₀ can be adjacent (e.g., formed on) and wrap a portion of side wall 451W of dielectric portion 451P. For example, shown in FIG. 9B, conductive contacts 665₀ can wrap the left portion (in the X-direction) portion of side wall 451W of dielectric portion 451P. In a similar but opposite way, conductive contacts 665₁ can be adjacent (e.g., formed) and wrap another portion of side wall 451W of dielectric portion 451P. For example, shown in FIG. 9B, conductive contacts 665₁ can wrap the right portion (in the X-direction) of side wall 451W of dielectric portion 451P.

As shown in FIG. 9A, conductive contacts 665₀ and 665₁ can be located at edges 532E₀ and 532E₁ of respective control gates associated with signals WLi₀ and WLi₁. Edges 532E₀ and 532E₁ are adjacent each other in the X-direction (e.g., directly opposite from each other in the X-direction). Edge 532E₀ is the edge of the conductive material 532 (in block BLK0) that forms control gate associated with signal WLi₀. Edge 532E₁ is the edge of the conductive material 532 (in block BLK1) that forms control gate associated with signal WLi₁. Other conductive contacts of blocks BLK0 and BLK1 have similar structures as conductive contacts 665₀ and 665₁ shown in FIG. 9A and FIG. 9B.

Memory device 200 including conductive contacts 665₀ and 665₁ as described allows memory device 200 to have a relatively small region (e.g., small area) for conductive contacts (e.g., conductive contacts 665₀ and 665₁) associated with control gates of memory device 200. This can lead to improvement in cost. Further, memory device 200 including conductive contacts 665₀ and 665₁ can mitigate or prevent damage (e.g., tier collapse, tier bending, or both) in part of memory device 200 (e.g., at the locations of conductive contacts 665₀ and 665₁) during processing. This can improve yield and cost. Moreover, the absence of tier collapse and tier bending allows memory device 200 to maintain proper electrical connections between circuit elements (e.g., less susceptible to electrical short between circuit elements) of memory device 200. This can lead to improvement in at least one of performance and reliability of memory device 200.

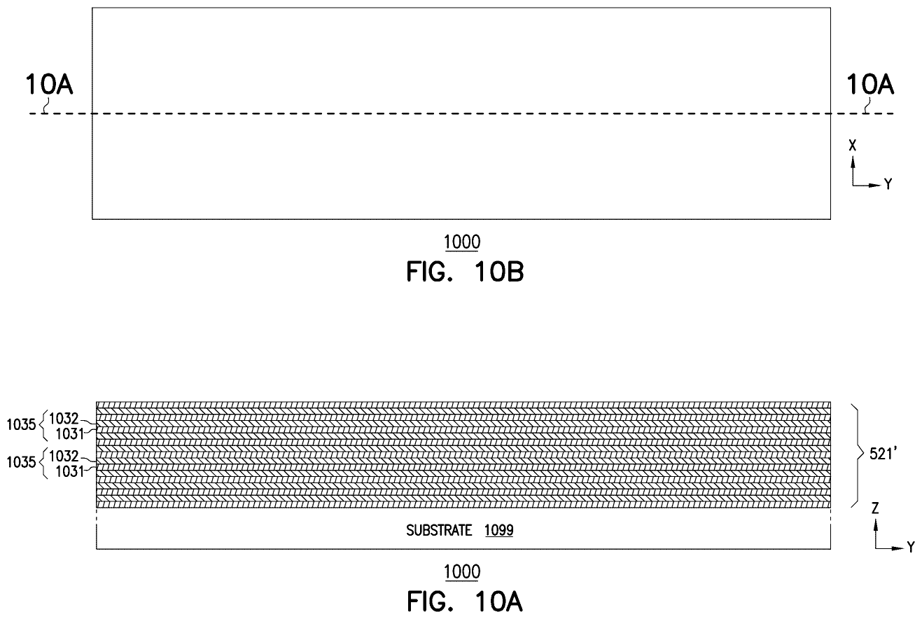

The above description with reference to FIG. 2 through FIG. 9B describes the structure of memory device 200. Some or all of the structure of memory device 200 can be formed using processes associated with the processes described below with reference to FIG. 10A through FIG. 27C.

FIG. 10A through FIG. 27C show different views of elements during processes of forming a memory device 1000, according to some embodiments described herein. FIG. 10A shows a side view (e.g., cross-section) in the Y-Z direction of a portion of memory device 1000 at line 10A of FIG. 10B. FIG. 10B is a top view (in the X-Y direction) of a portion of memory device 1000.

The processes associated with FIG. 10A and FIG. 10B can include forming dielectric materials (levels of dielectric materials) 1031 and dielectric materials (levels of dielectric materials) 1032 over a substrate 1099. Dielectric materials 1031 can include silicon dioxide. Dielectric materials 1032 can include silicon nitride. Dielectric materials 1031 and 1032 can be sequentially formed one material after another over substrate 1099 in an interleaved fashion, such that dielectric materials 1031 can be interleaved with dielectric materials 1032.

As shown in FIG. 10A, dielectric materials 1031 and 1032 can form tiers (tiers of materials) 1035. Tiers 1035 are located one over another in the Z-direction. Each tier 1035 can include a respective level of dielectric material 1031 and a respective level of dielectric material 1032. As shown in FIG. 10A, tiers 1035 can be included in a deck 521′ of memory device. In the processes described herein (FIG. 10A through FIG. 47), decks 521′, 522′, and 523′ can correspond to decks 521, 522, and 523 of FIG. 5.

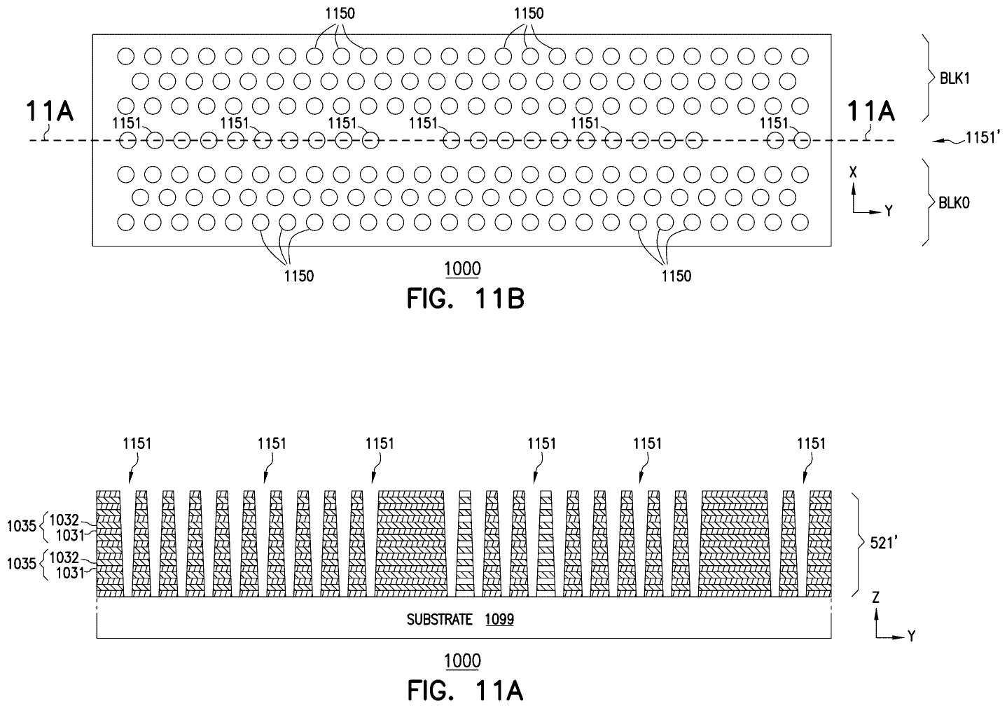

FIG. 11A and FIG. 11B show memory device 1000 after openings (e.g., holes) 1150 and 1151 are formed. Openings 1151 can be formed in region 1151′, which is between blocks BLK0 and BLK1. In subsequent processes of forming memory device 1000, conductive contacts (like conductive contacts 665₀ and 665₁ of memory device 200 of FIG. 7, FIG. 8, and FIG. 9A) can be formed in region 1151′.

As shown in FIG. 11B, openings 1150 can be formed in respective regions of memory device 1000 that includes blocks BLK0 and BLK1. In subsequent processes of forming memory device 1000, part of memory cell strings of memory device 1000 can be formed at the locations of respective openings 1150. FIG. 11B shows a small number of openings 1150 for simplicity. In reality, numerous openings 1150 can be formed.

Forming openings 1150 and 1151 can include removing (e.g., etching) a portion of dielectric materials 1031 and 1032 at the locations of openings 1150 and 1151. In FIG. 11B, region 1151′ is similar to the region of memory device 200 where dielectric structure 451 (FIG. 4 and FIG. 6) is located.

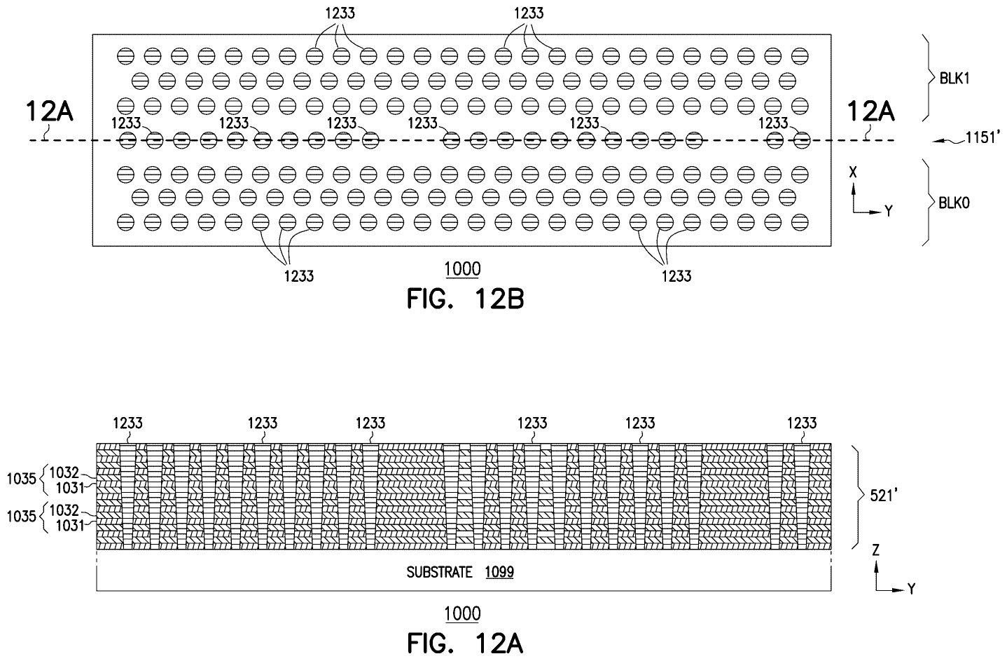

FIG. 12A and FIG. 12B show memory device 1000 after a material (or materials) 1233 is formed (e.g., filled) in openings 1150 and 1151. In subsequent processes of forming memory device 1000, material 1233 can be removed (e.g., removed at different times) from openings 1150 and 1151. Thus, material 1233 can be called a sacrificial material. An example of material 1233 can include carbon or other materials. Forming material 1233 can include forming a material (e.g., carbon) in openings 1150 and 1151. A chemical mechanical polishing (CMP) process can be performed after material 1233 is formed.

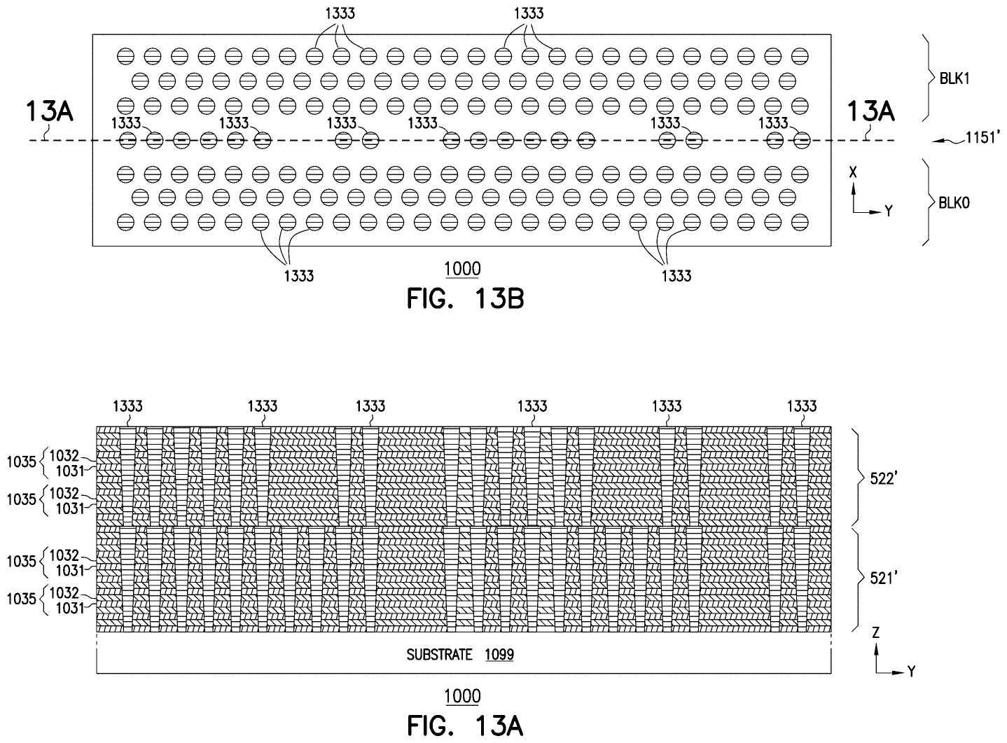

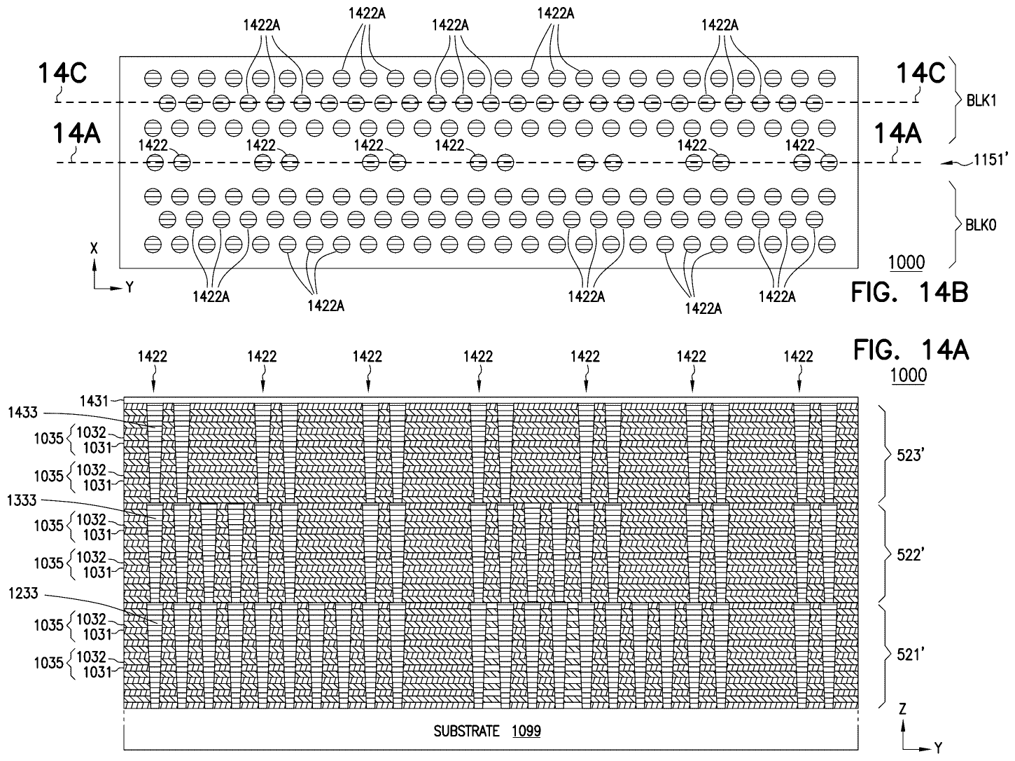

FIG. 13A and FIG. 13B show memory device 1000 after additional dielectric materials 1031 and dielectric materials 1032 (additional tiers) of deck 522′ are formed over deck 521′. Forming deck 522′ can be similar to forming deck 521′ described above. Thus, for simplicity, some of the processes (process steps) are not shown. For example, the processes associated with forming deck 522′ in FIG. 13A can include forming openings in dielectric materials 1031 and dielectric materials 1032 of deck 522′, then forming a material (e.g., sacrificial) 1333 (FIG. 13A) in the openings.

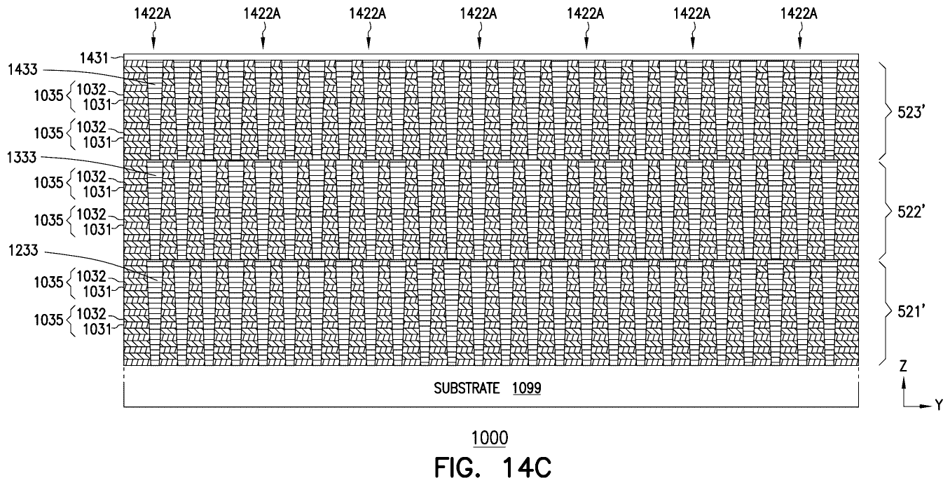

FIG. 14A, FIG. 14B, and FIG. 14C show memory device 1000 after additional dielectric materials 1031 and dielectric materials 1032 (additional tiers) of deck 523′ are formed over deck 522′. FIG. 14A and FIG. 14C show side views of memory device 1000 at lines 14A and 14C of FIG. 14B.

Forming deck 523′ in FIG. 14A can be similar to forming deck 521′ described above. Thus, for simplicity, some of the processes (process steps) are not shown. For example, the processes associated with forming deck 523′ in FIG. 14A can include forming openings in dielectric materials 1031 and dielectric materials 1032 of deck 523′, then forming a material (e.g., sacrificial) 1433 (FIG. 14A) in the openings. The processes associated with FIG. 14A and FIG. 14B can include forming material 1431 over deck 523′.

Each of pillars 1422 and 1422A can include materials 1233, 1333, and 1433 in respective decks 521′, 522′, and 523′. Pillars 1422 can be formed in region 1151 of decks 521′, 522′, and 523′. Pillars 1422A can be formed in the regions (memory array region) of blocks BLK0 and BLK1 of decks 521′, 522′, and 523′.

As shown in 14A, FIG. 14B, and FIG. 14C, pillars 1422 and 1422A can be formed in the same way and have the same profiles (e.g., same shape). However, pillars 1422 and 1422A can be formed for different purposes, as described below.

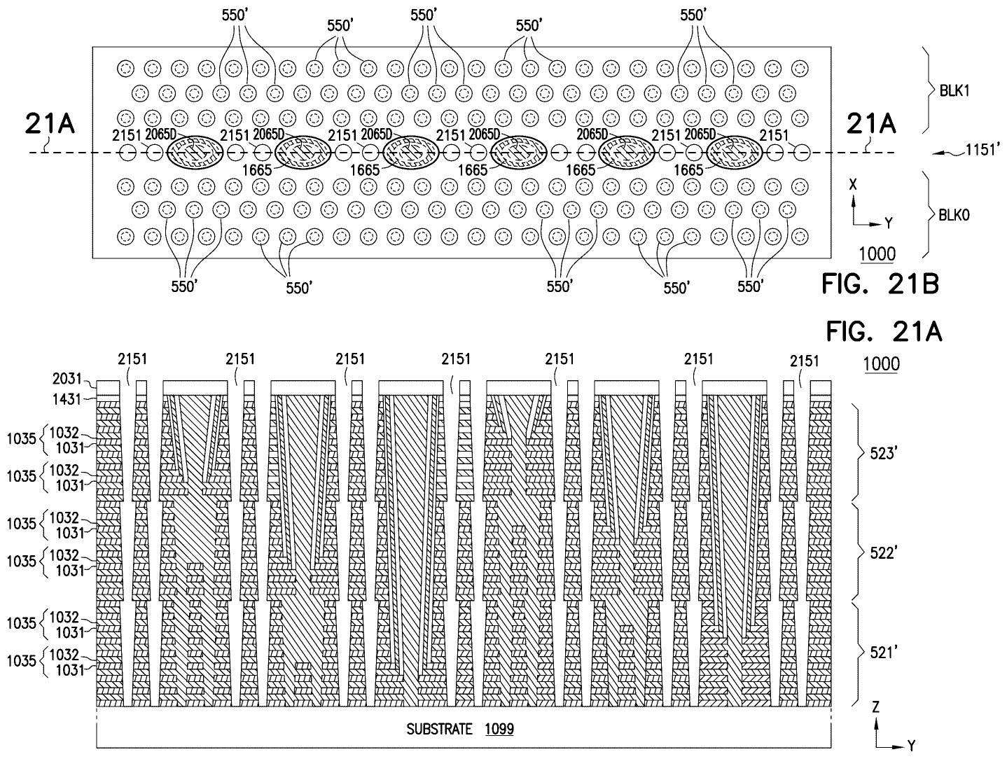

In subsequent processes associated with forming memory device 1000, materials 1233, 1333, and 1433 in pillars 1422 can be removed (in FIG. 21A) as part of forming conductive contacts of memory device 1000.

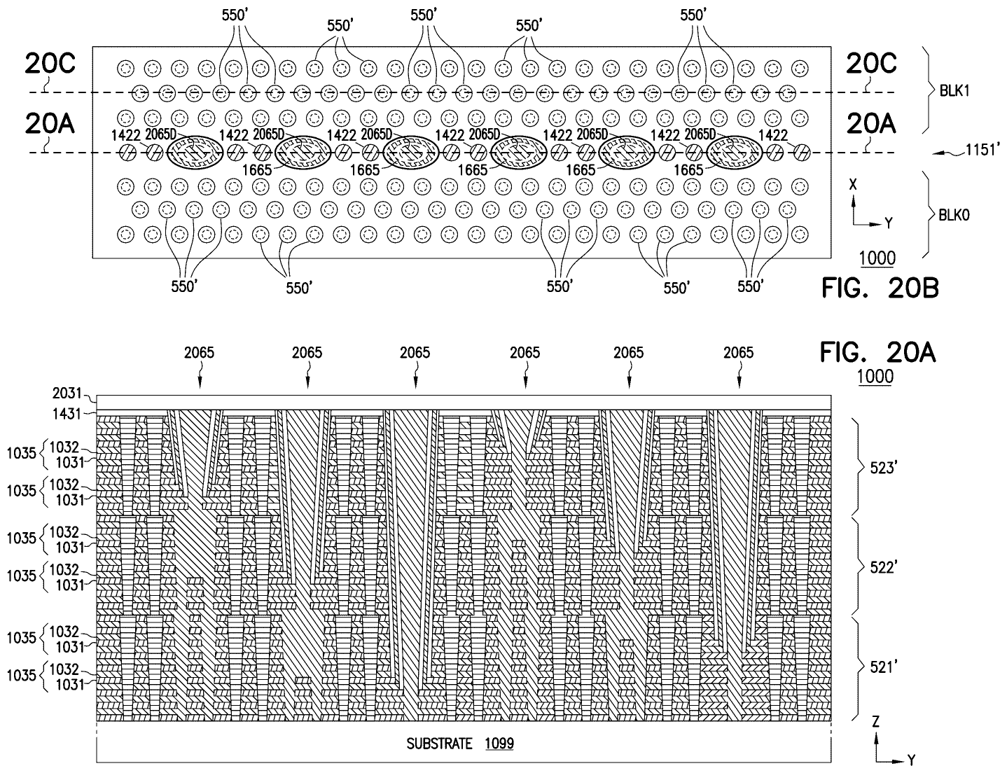

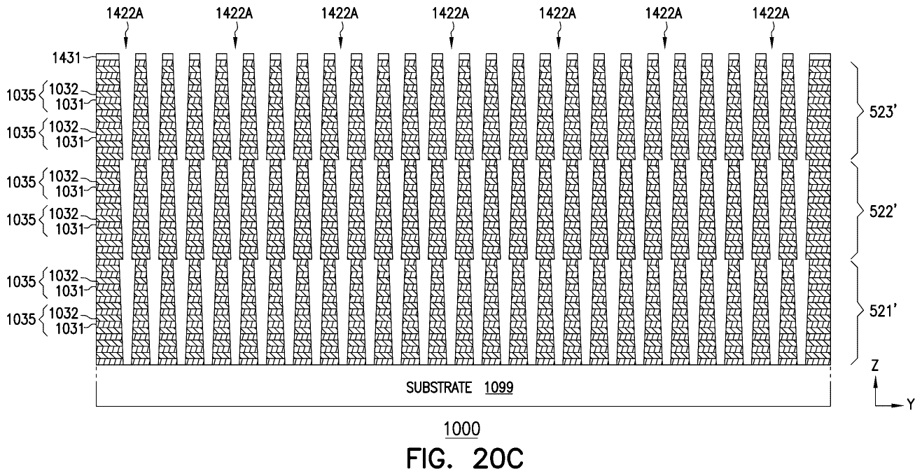

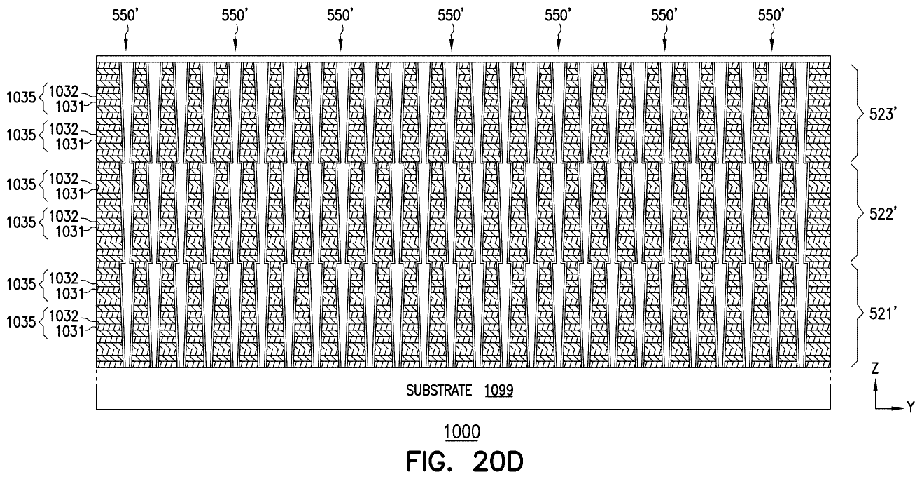

In subsequent processes associated with part of forming memory cells of memory device 1000 (as described below with reference to FIG. 20A), materials 1233, 1333, and 1433 in pillars 1422A of FIG. 14C can be removed to form memory cells and associated with pillars (memory cell pillars) of blocks BLK0 and BLK1 of memory device 1000.

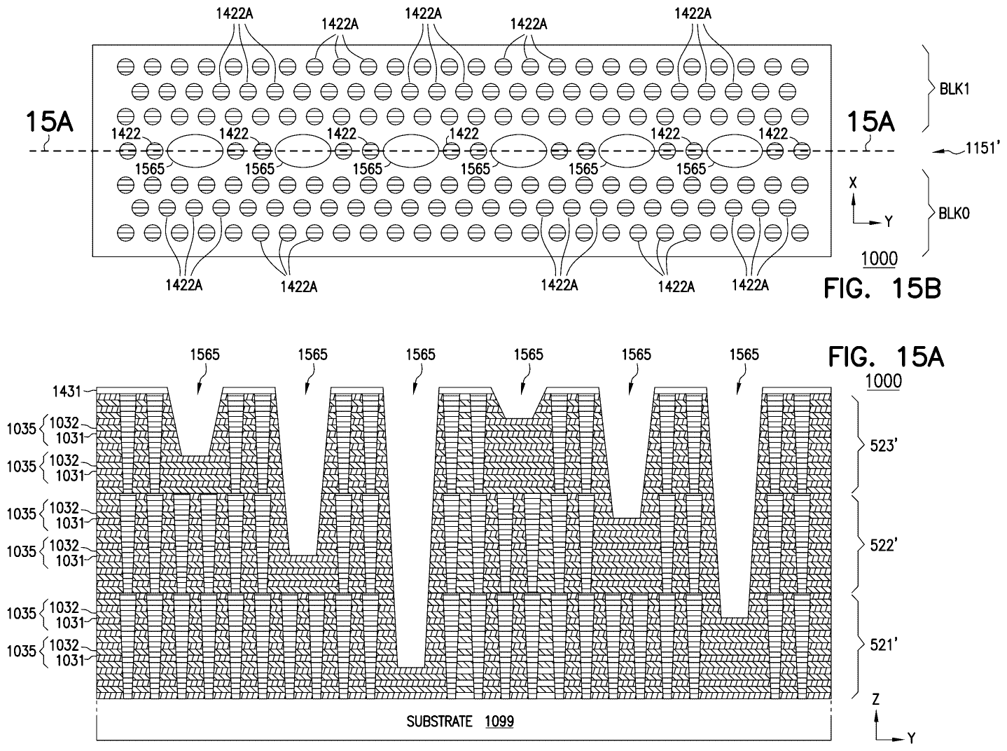

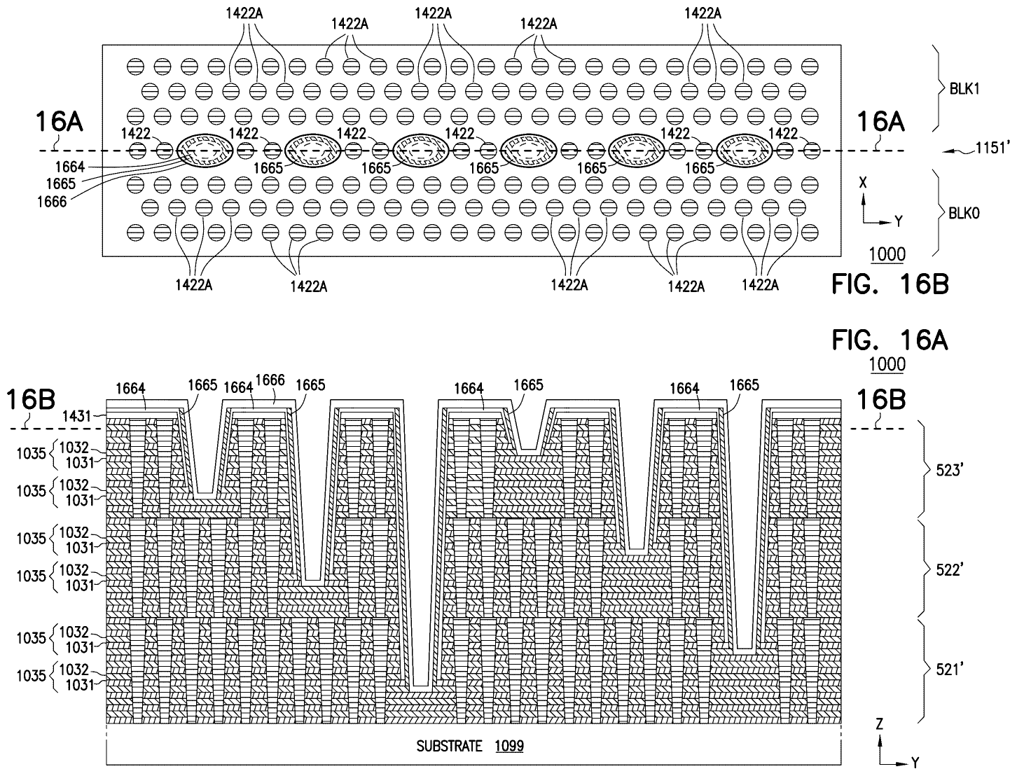

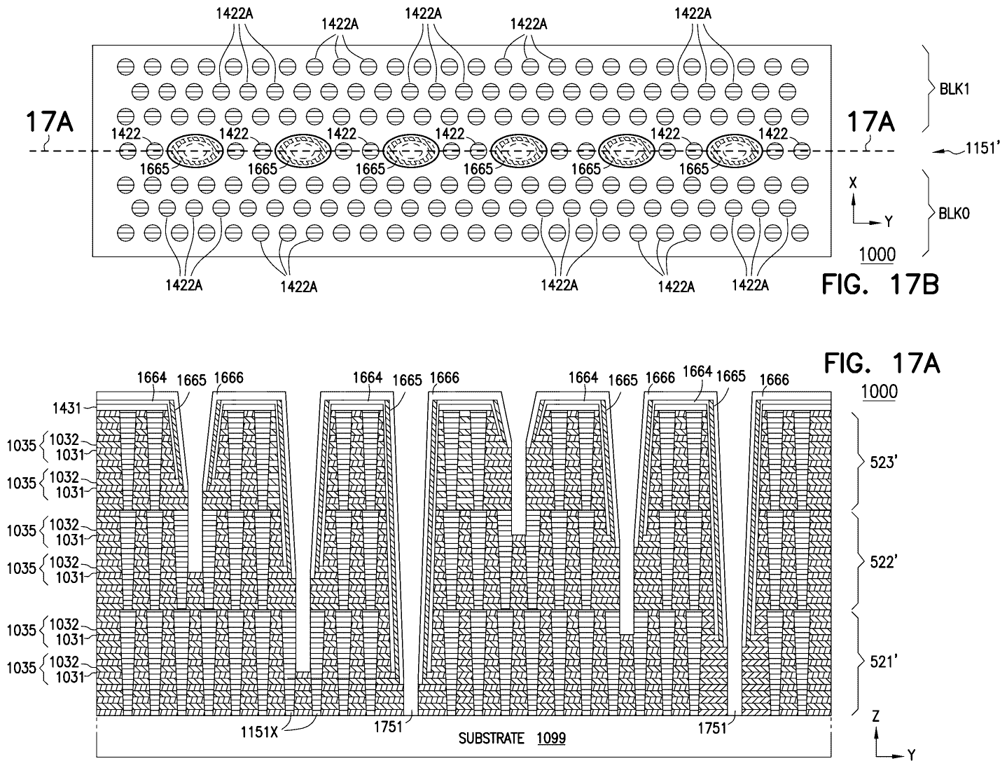

In the following processes associated with FIG. 15A through FIG. 19A and FIG. 19B, the materials (e.g., pillars 1422A) in the regions (e.g., memory array regions) of blocks BLK0 and BLK1 are covered (e.g., masked) while the processes are performed at region 1151′. Thus, materials (e.g., sacrificial materials) 1233, 1333, and 1433 formed in the regions of blocks BLK0 and BLK1 can remain (not be removed) while the processes are performed at region 1151′. In the processes associated with FIG. 20A and FIG. 20B, the regions (memory array regions) of blocks BLK0 and BLK1 can be uncovered (e.g., unmasked). After uncovering, memory cells and associated pillars (memory cell pillars) can be formed at the regions of block BLK0 and BLK1.

FIG. 15A and FIG. 15B show memory device 1000 after contact openings (e.g., holes) 1565 are formed. Contact openings 1565 can be formed in region 1151′, which is between blocks BLK0 and BLK1. Forming contact openings 1565 can include removing a portion of dielectric materials 1031 and 1032 in region 1151′ at the locations of contact openings 1565. In subsequent processes of forming memory device 1000, conductive contacts (e.g., like conductive contacts 665₀ and 665₁ in FIG. 7, FIG. 8, and FIG. 9A) and structures (e.g., dielectric contact structures 2065 in FIG. 20A) are formed at the locations of contact openings 1565.

FIG. 16A and FIG. 16B show memory device 1000 after spacers 1664, 1665, and 1666 are formed. Spacers 1664, 1665, and 1666 include dielectric materials. For example, spacers 1664, 1665, and 1666 can include silicon dioxide, silicon nitride, and silicon dioxide, respectively. For ease of viewing spacers 1664, 1665, and 1666 in FIG. 16A and FIG. 16B (and other figures described herein), spacers 1664 and 1665 are not drawn with hatch lines (diagonal lines). Further, the labels for spacers 1664 and 1666 are sometimes omitted from the figures to avoid crowding of elements shown in the figures.

FIG. 17A and FIG. 17B show memory device 1000 after a portion of material directly under contact openings 1565 is removed to form cuts 1751 under respective contact openings 1565. For simplicity, only two of the cuts 1751 are labeled in FIG. 17A. Cuts 1751 are open spaces (e.g., holes). Cuts 1751 can be formed to expose the deepest openings (e.g., openings 1151X in deck 521′) that were filled with sacrificial material (e.g., material 1233).

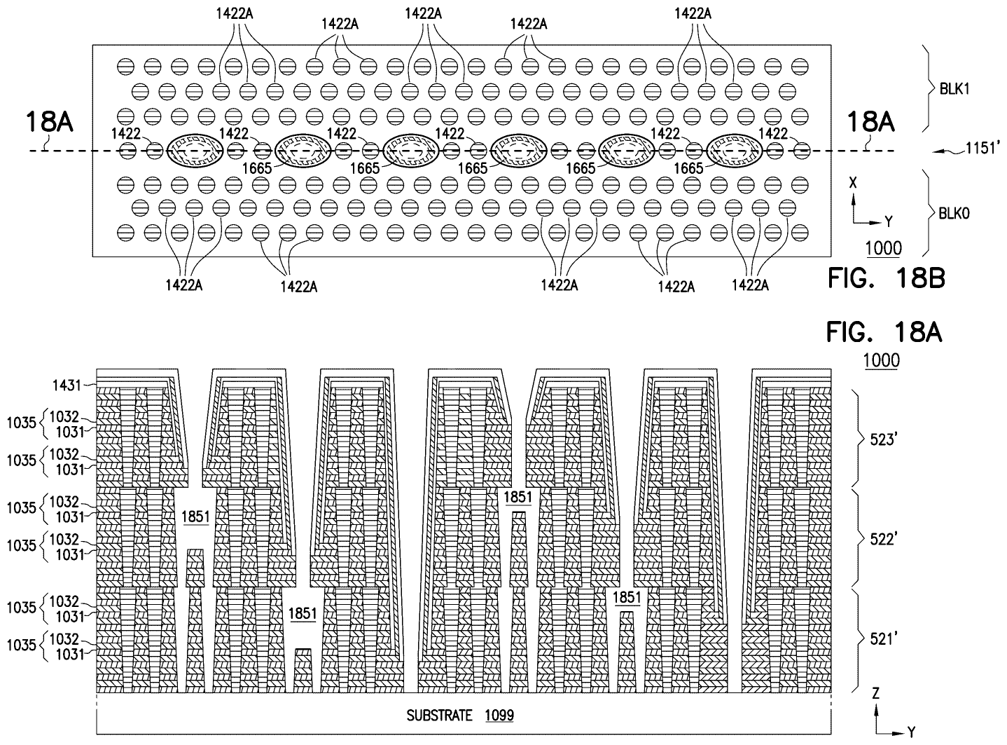

FIG. 18A and FIG. 18B show memory device 1000 after material 1233 and 1333 (sacrificial materials) at a portion of deck 521′ and a portion of deck 522′ are removed′ (e.g., exhumed) through cuts 1751. As shown in FIG. 18A, open spaces 1851 are formed at the locations where materials 1233 and 1333 were removed.

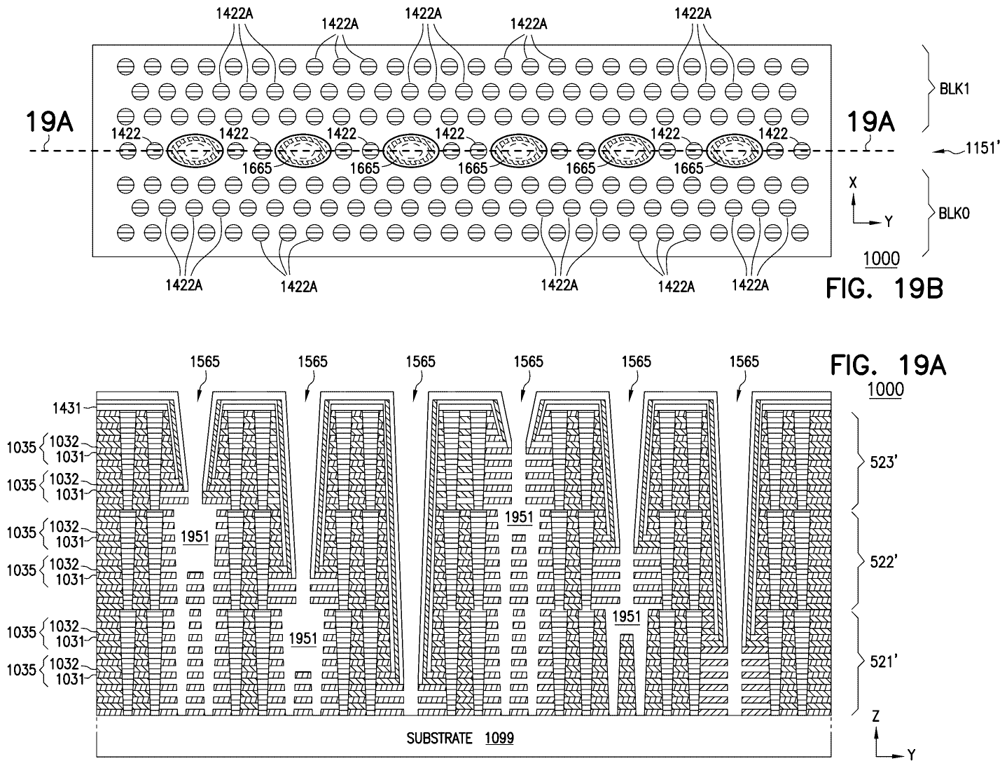

FIG. 19A and FIG. 19B show memory device 1000 after a removal of dielectric materials 1032 (e.g., silicon nitride of tiers 1035) that were exposed at open spaces 1851 in FIG. 18A. An etch process can be used to remove dielectric materials 1032. As shown in FIG. 19A, open spaces 1951 are formed under respective contact openings 1565. Open spaces 1951 include open spaces 1851 and the spaces that the removed dielectric materials 1032 occupied in FIG. 18A.

FIG. 20A and FIG. 20B show memory device 1000 after dielectric contact structures 2065 are formed. Forming dielectric contact structures 2065 and include forming (e.g., filling) a dielectric material (e.g., silicon dioxide) 2065D in open spaces 1951 and contact openings 1565 of FIG. 19A. A CMP process can be performed after material 2065D is formed. A dielectric material 2031 can also be formed.

FIG. 20C shows a side view (e.g., cross-section like FIG. 14C) of memory device 1000 at line 20C of FIG. 20B after materials 1233, 1333, and 1433 are removed from the locations of pillars 1422A.

FIG. 20D shows memory device 1000 of FIG. 20C after memory cells (not labeled) and associated pillars 550′ are formed at the locations of opening 1442A (FIG. 20C). The memory cells and associated pillars 550′ of memory device 1000 of FIG. 20B and FIG. 20D are similar to memory cells 210, 211, 212, and pillars 550, respective, of memory device 200 of FIG. 5.

The processes of forming memory cells and associated pillars 550′ associated with FIG. 20D can include forming elements that can include storage charge structures and channels (e.g., pillar channel) of the memory cells. After the memory cells and pillars 550′ are formed, they can be covered (e.g., masked) while additional processes are performed at region 1151 and pillars 1422, as described below.

FIG. 21A and FIG. 21B show memory device 1000 after openings 2151 are formed in the location of pillars 1422 (labeled in FIGS. 14A and 14B and FIG. 20B). Forming openings 2151 can include patterning and removing materials 1233, 1333, and 1433 from respective pillars 1422. The processes associated with FIG. 21A and FIG. 21B can also include forming dielectric structures (like dielectric structures 451 in FIG. 4) to separate (electrically separate) word lines of block BLK0 from an adjacent block (not shown) and word lines of block BLK1 from an adjacent block (not shown).

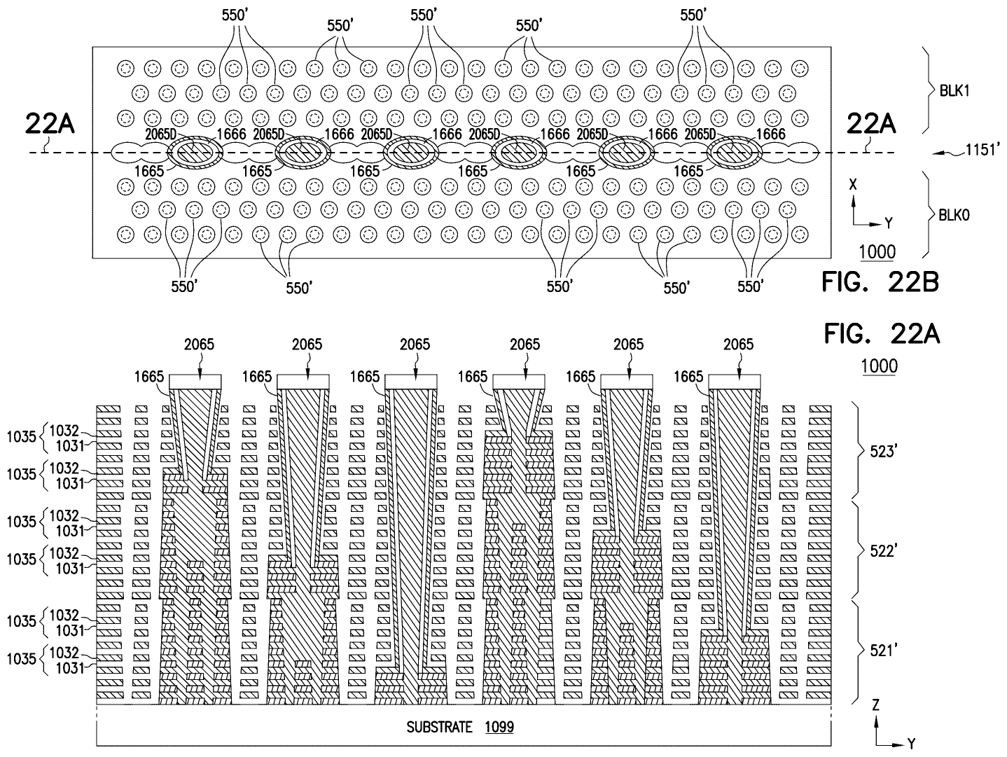

FIG. 22A and FIG. 22B show memory device 1000 after dielectric materials (e.g., silicon dioxide) 1031 at region 1151 are removed. As shown in FIG. 22A, spacers (e.g., silicon nitride spacer) 1665 are exposed at respective structures (e.g., dielectric contact structures) 2065.

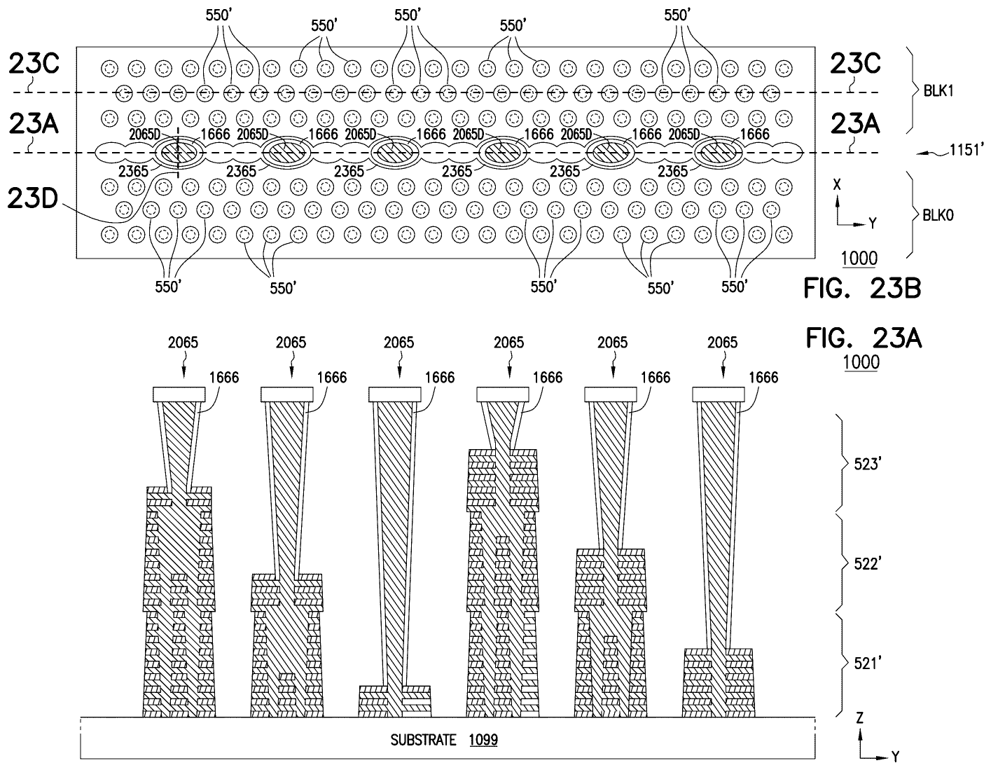

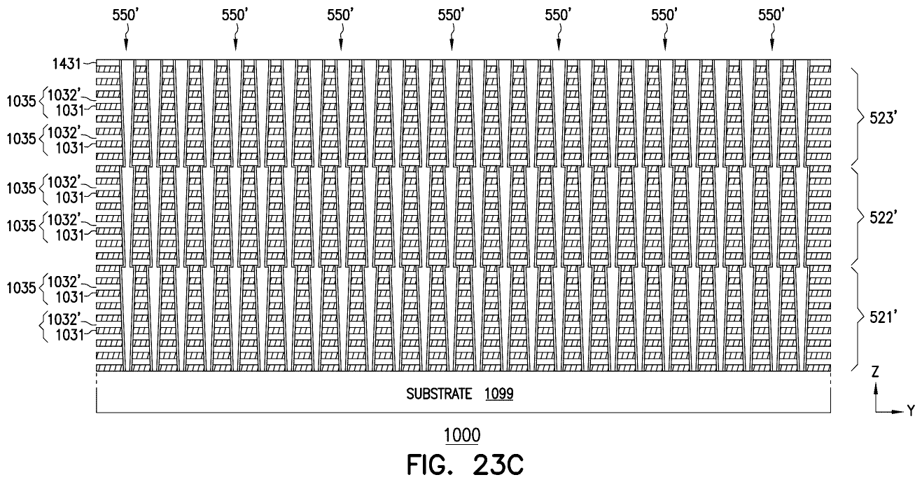

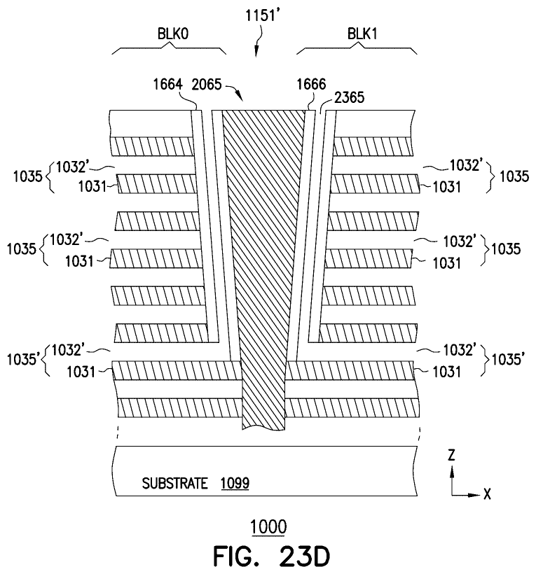

FIG. 23A and FIG. 23B show memory device 1000 after spacers 1665 (labeled in FIG. 22A) are removed. In FIG. 23B, openings 2365 (which have oval shapes) were the locations of spacers 1665 in FIG. 22A before spacers were removed.

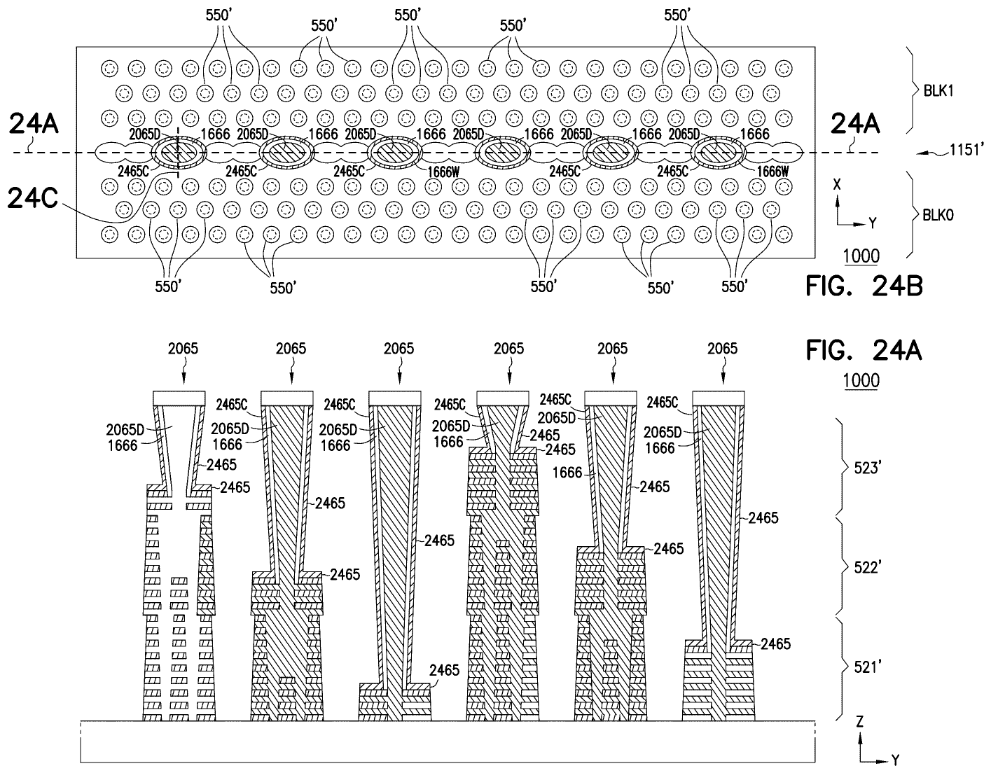

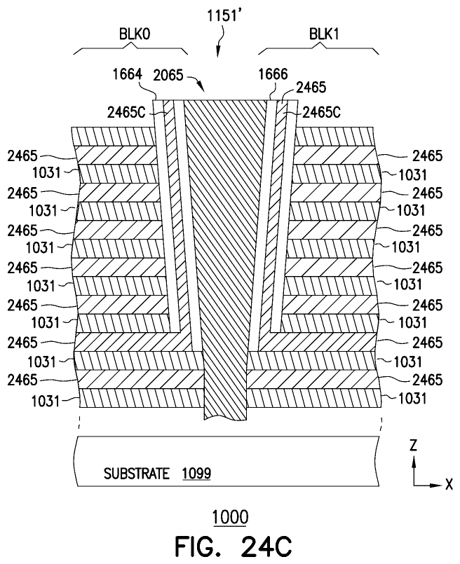

FIG. 23A and FIG. 23C show memory device 1000 after dielectric materials (e.g., silicon nitride) 1032 at the regions (memory array region) of blocks BLK0 and BLK1 are removed (e.g., exhumed) from locations 1032′ in FIG. 23C. Locations 1032′ in FIG. 23C are voids (empty spaces) that were occupied by dielectric materials 1032 (as shown in FIG. 14) before dielectric materials 1032 were removed in FIG. 23C. In subsequent processes (FIG. 24C), conductive materials can be formed in locations 1032′ to form respective control gates of memory device 1000.

FIG. 23D shows a side view (e.g., cross-section) at line 23D of FIG. 23B including one of dielectric contact structures 2065 in region 1151′ and portions of blocks BLK0 and BLK1 of memory device 1000. In FIG. 23D, tier 1035′ is one of the tiers in respective blocks BLK0 and BLK1. As shown in FIG. 23D, opening 2365 can joint (form a continuous access path) with voids (empty spaces) at locations 1032′ in tiers 1035′ of respective blocks BLK0 and BLK1. Tiers 1035′ of respective blocks BLK0 and BLK1 that are coupled to opening 2365 can be located in the same level in the Z-direction. In subsequent processes (FIG. 24C), a conductive material (e.g., conductive material 2465 in FIG. 24C) can be concurrently formed in opening 2365 and in locations 1032′. As described below, the conductive material (conductive material 2465 in FIG. 24C) in locations 1032′ forms control gates of blocks BLK0 and BLK1. The conductive material (the same conductive material 2465 in FIG. 24C) in opening 2365 (FIG. 23D) forms conductive contacts of block BLK0 and BLK1 associated with (contacting) respective control gates (which are also formed from conductive material 2465 in FIG. 24C). Thus, forming the conductive contacts and forming the control gates can occur concurrently (e.g., occur in situ).

FIG. 24A, FIG. 24B, and FIG. 24C show memory device 1000 after conductive material (or conductive materials) 2465 are formed in locations 1032′ (labeled in FIG. 23D) and in openings 2365 (labeled in FIG. 23D). Conductive material 2465 can be similar to or the same as conductive material 532 of FIG. 9A. For example, conductive material 2465 can include a single material (e.g., metal) or a combination of (e.g., different layers of) conductive materials (e.g., metal and other conductive material). For example, material 2465 can include tungsten or a combination of tungsten and other conductive materials (e.g., titanium nitride or other conductive materials).

As mentioned above, conductive material 2465 in locations 1032′ (labeled in FIG. 23D) forms control gates of blocks BLK0 and BLK1. The conductive material 2465 in openings 2365 (labeled in FIG. 23D) forms conductive contacts associated with respective control gates of blocks BLK0 and BLK1.

As shown in FIG. 24A and FIG. 24B, conductive material 2465 can form conductive structures 2465C adjacent respective spacers 1664 and 1666. Each conductive structure 2465C has a circular or oval shape, like a ring shape, from the top view. Each conductive structure 2465C can be adjacent and wrap around (e.g., can fully encircle) a side wall 1666W (FIG. 24B) of a respective spacer 1666 of a respective dielectric contact structure 2065. As shown in FIG. 24B, side wall 1666W is an outer side wall of spacer 1666 opposite from an inner side wall (not labeled) of spacer 1666. For simplicity, side wall 1666W of only two spacers 1666 are labeled in FIG. 24B.

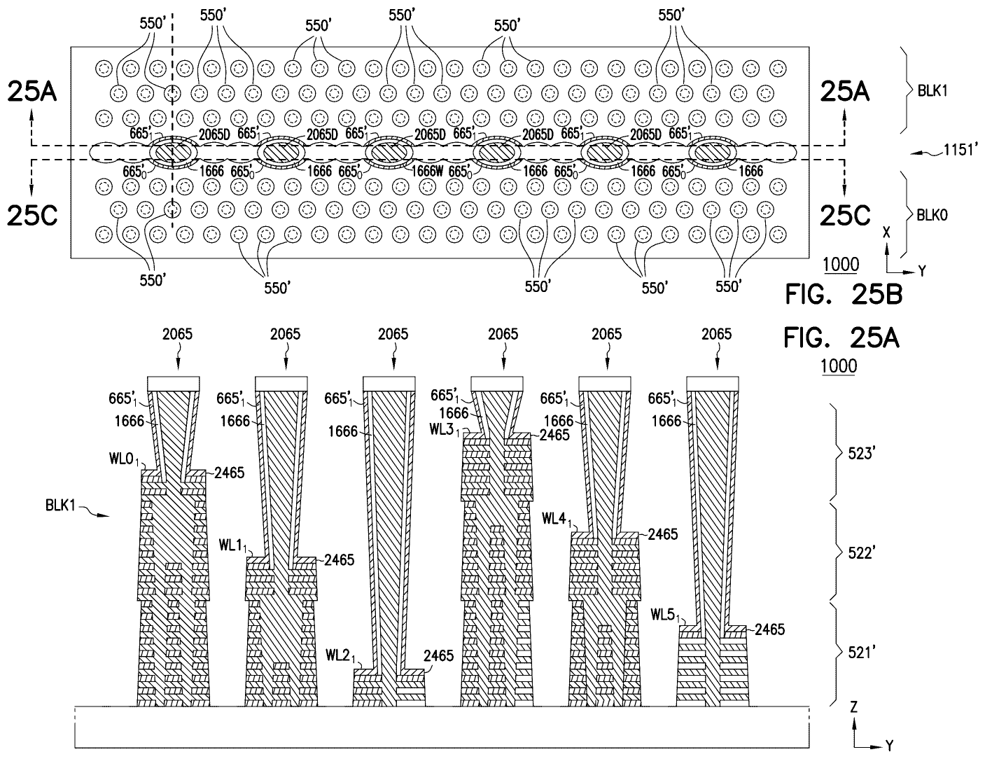

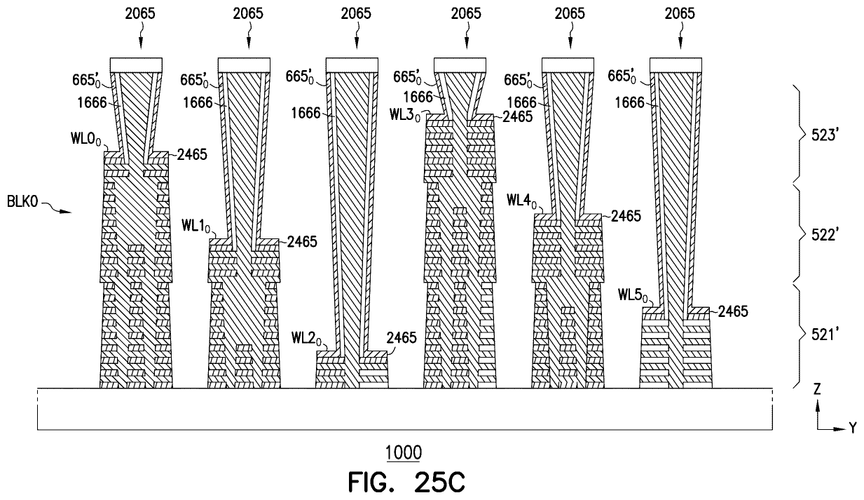

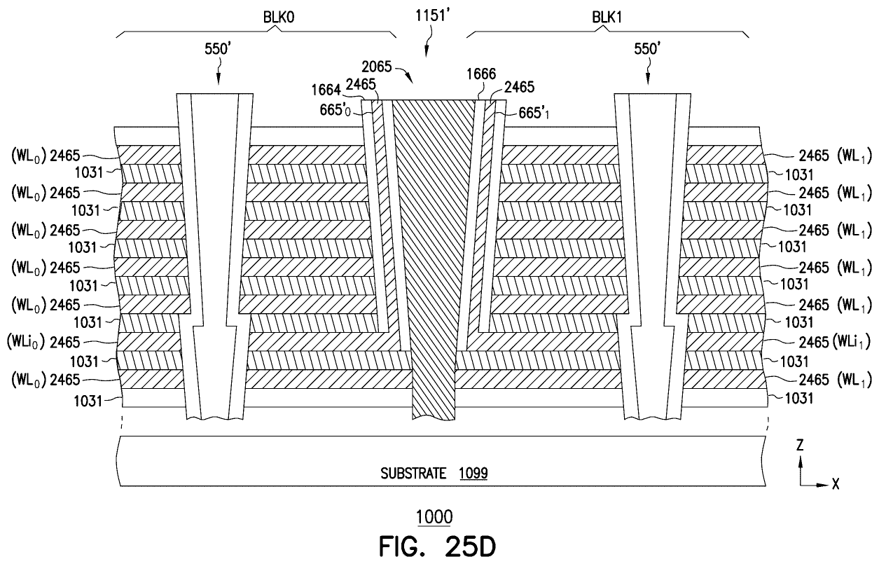

In subsequent processes (FIG. 25A, FIG. 25B, FIG. 25C, and FIG. 25D), each conductive structure 2465C can be divided into two portions (one pair of conductive contacts). The two portions (divided portions) form two conductive contacts associated two respective control gates of different blocks (one control gate in block BLK0 and another control gate in block BLK1).

FIG. 25A, FIG. 25B, FIG. 25C, and FIG. 25D show memory device 1000 after conductive contacts 665′o and 665′1 are formed in respective blocks BLK0 and BLK1. FIG. 25A shows a side view (e.g., cross-section) at line 25A of FIG. 25B including a portion of dielectric contact structure 2065 and conductive material 2465 associated with the control gates of block BLK1. FIG. 25C shows a side view (e.g., cross-section) at line 25C of FIG. 25B including a portion of dielectric contact structure 2065 and conductive material 2465 associated with the control gates of block BLK0. FIG. 25D shows a side view (e.g., cross-section) at line 25D of FIG. 25B including dielectric contact structure 2065, conductive material 2465 associated with the control gates of blocks BLK0 and BLK1, and pillars (memory cell pillars) 550′ of respective blocks BLK0 and BLK1.

FIG. 25A shows an example of some of the control gates of block BLK1 associated with signals WL0₁, WL1₁, WL2₁, WL3₁, WL4₁, and WL5₁. In FIG. 25D, signals WL₁ and WLi₁ are associated the control gates of block BLK1. Signals WL₁ and WLi₁ can correspond to some of signals WL0₁, WL1₁, WL2₁, WL3₁, WL4₁, and WL5₁ in FIG. 25A. Signal WLi₁ in FIG. 25D can represent one of signals WL0₁, WL1₁, WL2₁, WL3₁, WL4₁, and WL5₁ in FIG. 25A.

FIG. 25C shows an example of some of the control gates of block BLK0 associated with signals WL0₀, WL1₀, WL2₀, WL3₀, WL4₀, and WL5₀. In FIG. 25D, signals WL₀ and WLi₀ are associated the control gates of block BLK0. Signals WL₀ and WLi₀ can correspond to some of signals WL0₀, WL1₀, WL2₀, WL3₀, WL4₀, and WL5₀ in FIG. 25C. Signal WLi₀ in FIG. 25D can represent one of signals WL0₀, WL1₀, WL2₀, WL3₀, WL4₀, and WL5₀ in FIG. 25C.

In FIG. 25D, the control gate associated with signals WLi₀ and WLi₁ can represent (can be similar to or the same as) the control gates associated with signals WLi₀ and WLi₁, respectively, in FIG. 9A of memory device 200.

In FIG. 25A, FIG. 25B, FIG. 25C, and FIG. 25D, the processes of forming conductive contacts 665′₀ and 665′₁ can include removing (e.g., etching) portions of conductive material 2465 of conductive structures 2465C in FIG. 24B. As shown in FIG. 25B (top view) the portions on the left and right (in the Y-direction) of a respective conductive structure 2465C can be removed to divide each conductive structure 2465C into two remaining portions. One remaining portion (e.g., bottom portion in FIG. 25B) forms a conductive contact 665′₀ associated with a control gate of block BLK0. The other remaining portion (e.g., top portion in FIG. 25B) forms a conductive contact 665′₁ associated with a control gate of block BLK1. Conductive contacts 665′₀ and 665′₁ in FIG. 25A, FIG. 25B, FIG. 25C, and FIG. 25D can be similar to or the same as conductive contacts 665′₀ and 665′₁ of memory device 200 of FIG. 7, FIG. 8, and FIG. 9A.

As shown in FIG. 25B, each conductive contact 665′ has a semi-circular or semi-oval shape from the top view (like a shape of letter “C”). Each conductive contact 665′ can be adjacent and partially wrap (e.g., can wrap a portion of the outer side wall 1666W of spacer 1666) of a respective dielectric contact structure 2065. In FIG. 25A and FIG. 25C, the control gates of block BLK0 associated with signals WL0₀, WL1₀, WL2₀, WL3₀, WL4₀, and WL5₀ can be located on the same levels (similar to levels 502, 504, 506, 508, 510, and 512 in FIG. 5) as the control gates of block BLK1 associated with signals WL0₁, WL1₁, WL2₁, WL3₁, WL4₁, and WL5₁, respectively. Thus, conductive contacts 665′₀ and 665′₁ associated with the control gates located on the same levels (e.g., the control gates associated with signals WL0₀ and signals WL0₁) can have the same length (in the Z-direction).

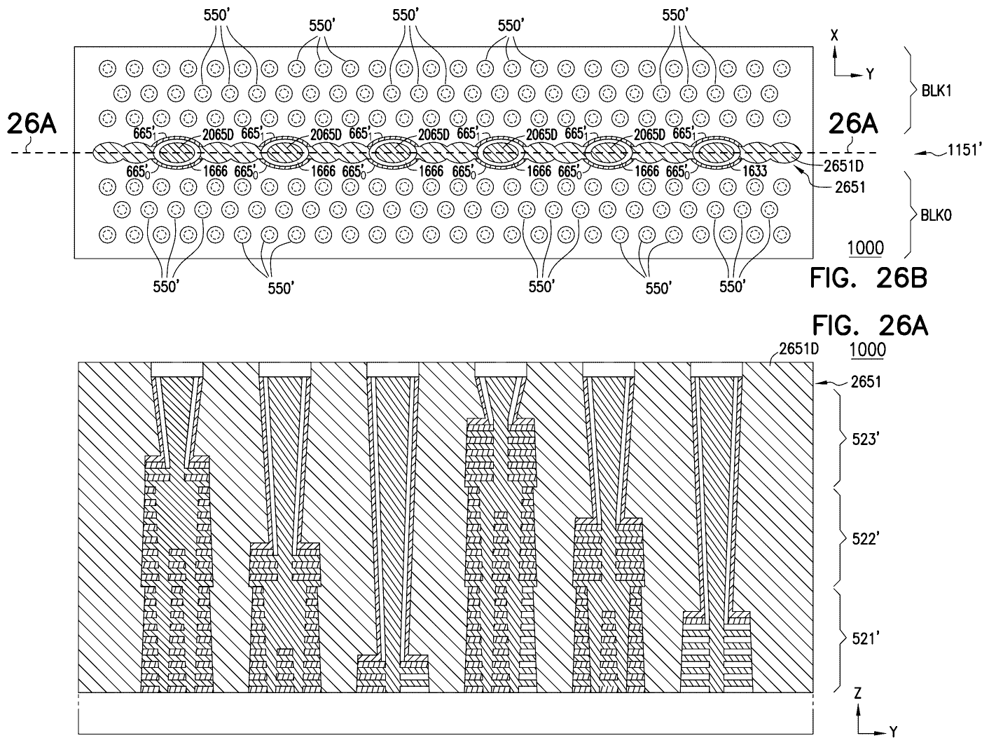

FIG. 26A and FIG. 26B show memory device 1000 after dielectric structure 2651 is formed in region 1151′. Forming dielectric structure 2651 can include forming (e.g., filling) a dielectric material (or materials) 2651 in region 1151′. Dielectric structure 2651 separate (physically separate) blocks BLK0 and BLK1 from each other. Thus, the control gates of block BLK0 (e.g., the control gates associated with signals WL0₀, WL1₀, WL2₀, WL3₀, WL4₀, and WL5₀ in FIG. 25C) are separated (physically and electrically separated) from the control gates of block BLK1 (e.g., the control gates associated with signals WL0₁, WL1₁, WL2₁, WL3₁, WL4₁, and WL5₁ in FIG. 25A) by material 2651D of dielectric structure 2651.

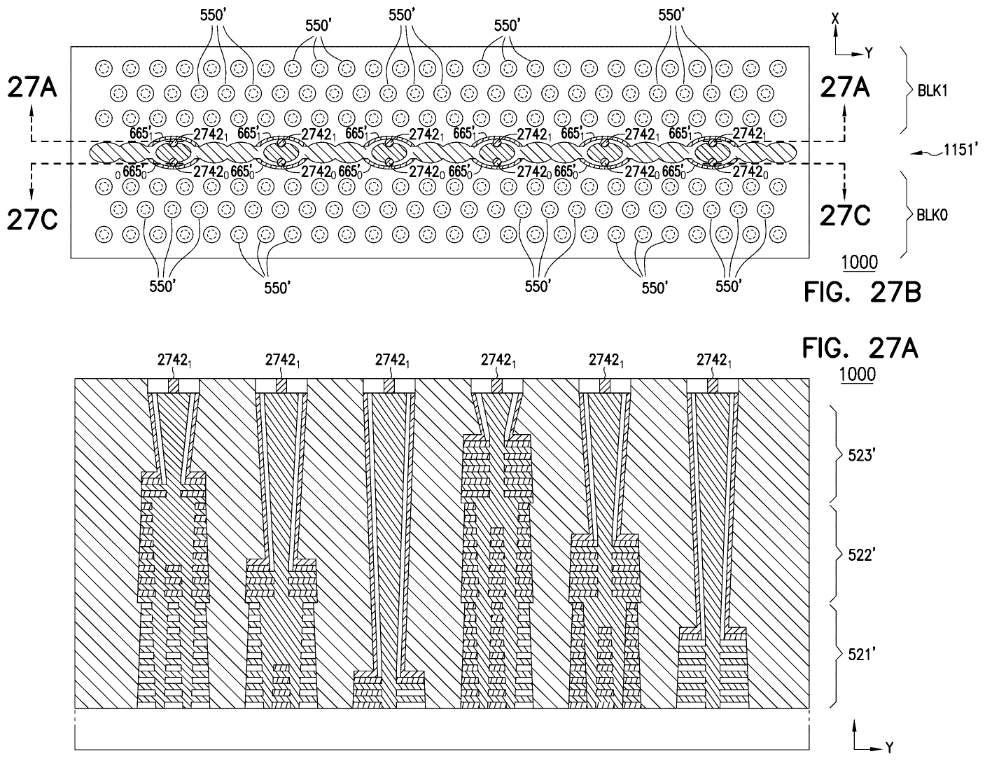

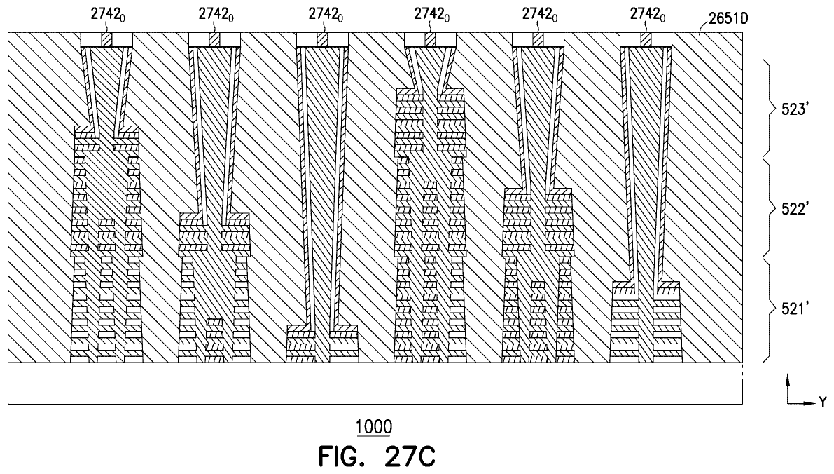

FIG. 27A, FIG. 27B, and FIG. 27C show memory device 1000 after conductive connections 2742₀ and 2742₁ are formed over (e.g., formed on) respective conductive contacts 665′₀ and 665₁′. In subsequent processes (not described), conductive lines (e.g., conductive routings) of memory device 1000 can be formed to connect conductive connections 2742₀ and 2742₁ to other components (e.g., word line drivers) of memory device 1000.

The processes of forming memory device 1000 described above with reference to FIG. 12A through FIG. 27C can include other processes to form a complete memory device (e.g., memory device 1000). Such processes are omitted from the above description so as not to obscure the subject matter described herein. Improvements and benefits of memory device 1000 are similar to or the same as improvements and benefits of memory device 200 described above.

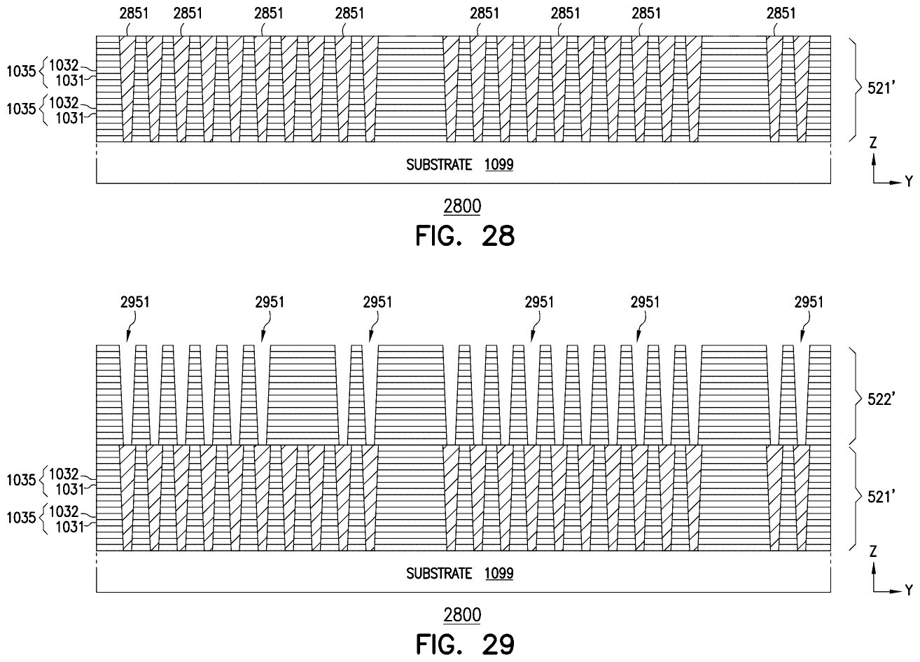

FIG. 28 through FIG. 35 show different views of elements during processes of forming a memory device 2800, according to some embodiments described herein. Some of the processes and materials used in forming memory device 2800 are similar to or the same as the processes of forming memory device 1000. Thus, for simplicity, detailed description of similar or the same process and materials are not repeated. Also, for simplicity, cross-sectional lines (e.g., hatch lines) are omitted from some or all the elements shown in FIG. 28 through FIG. 35.

FIG. 28 shows memory device 2800 after pillars 2851 are formed in dielectric materials 1031 and 1032 of deck 521′. Pillars 2851 can include (e.g., can be filled with) a sacrificial material like material 1233 in FIG. 12A.

FIG. 29 shows memory device 2800 after additional dielectric materials 1031 and dielectric materials 1032 (additional tiers) of deck 522′ are formed over deck 521′. The processes associated with FIG. 29 also include forming openings 2951 in deck 522′.

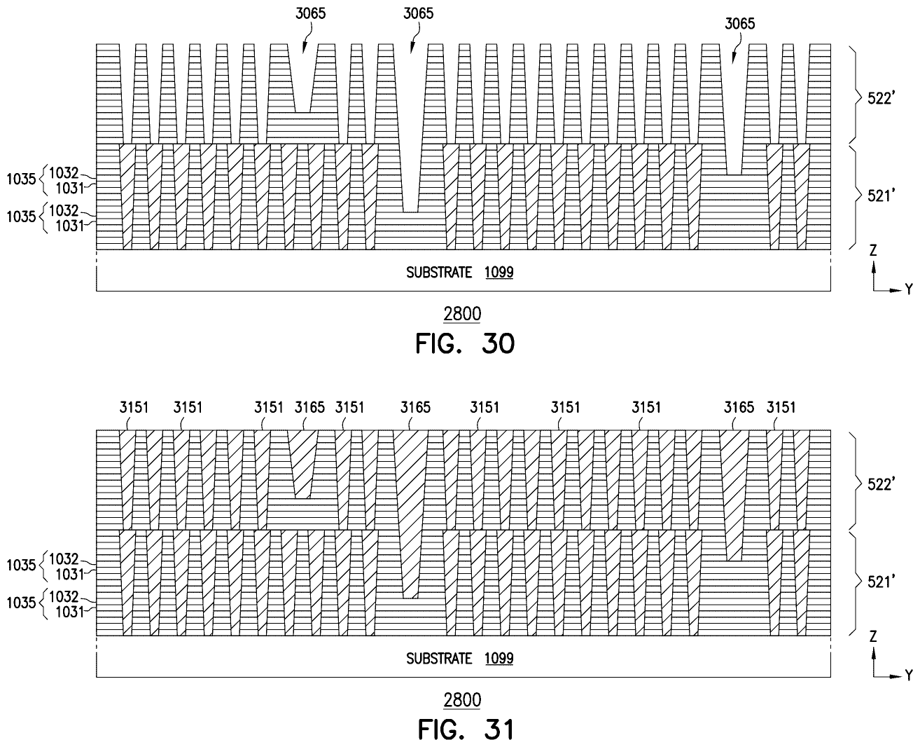

FIG. 30 shows memory device 2800 after openings 3065 are formed in dielectric materials 1031 and 1032 of deck 521′ and 522′.

FIG. 31 shows memory device 2800 after pillars 3151 and pillars 3165 are formed by forming a sacrificial material in openings 2951 of FIG. 29 and opening 3065 of FIG. 30.

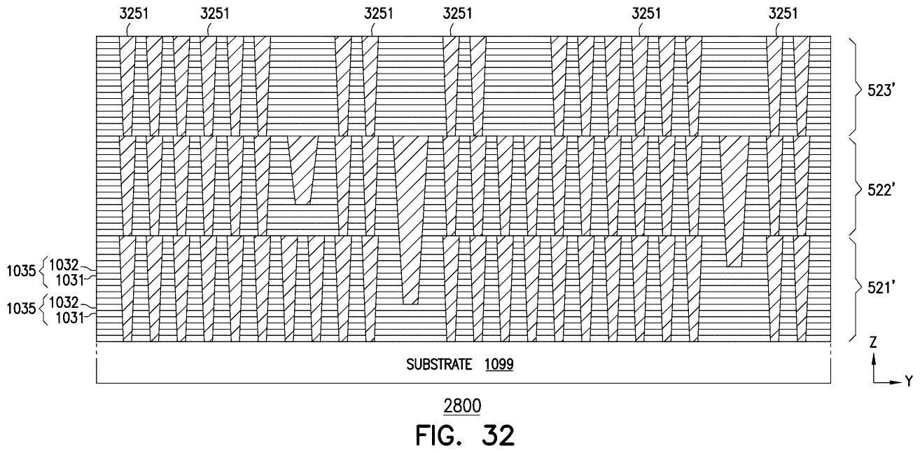

FIG. 32 shows memory device 2800 after additional dielectric materials 1031 and dielectric materials 1032 (additional tiers) of deck 523′ are formed over deck 522′. The processes associated with FIG. 32 also include forming pillars 3251 in deck 523′. Forming pillars 3251 can include forming openings in deck 523′ and forming (e.g., filling) the openings in deck 523′ with a sacrificial material.

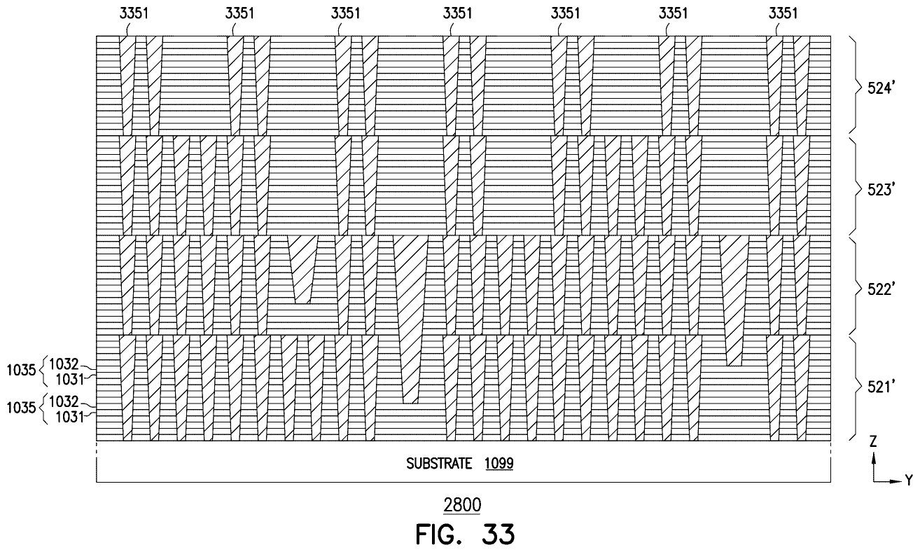

FIG. 33 shows memory device 2800 after additional dielectric materials 1031 and dielectric materials 1032 (additional tiers) of deck 524′ are formed over deck 523′. The processes associated with FIG. 33 also include forming pillars 3351 in deck 524′. Forming pillars 3351 can include forming openings in deck 524′ and forming (e.g., filling) the openings in deck 524′ with a sacrificial material.

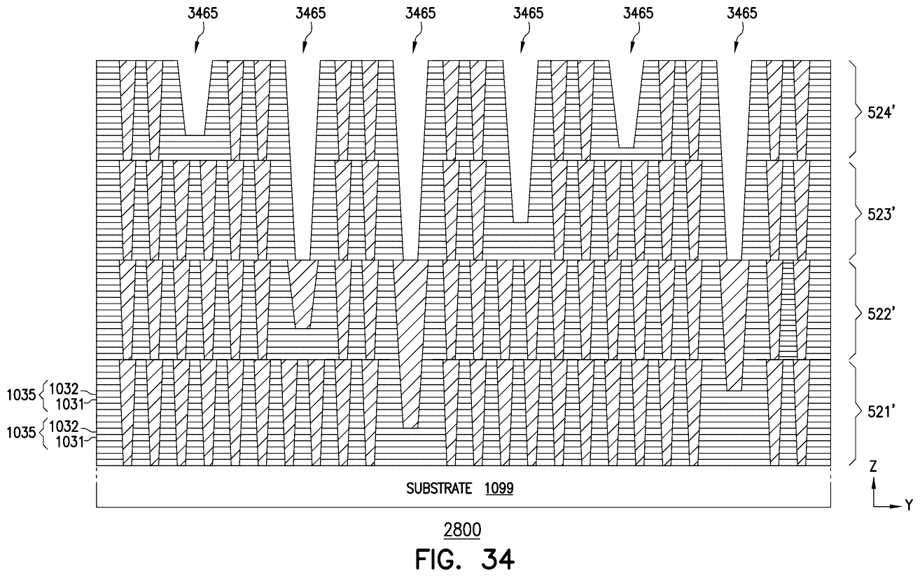

FIG. 34 shows memory device 2800 after contact openings 3465 are formed in dielectric materials 1031 and 1032 of decks 523′ and 524′.

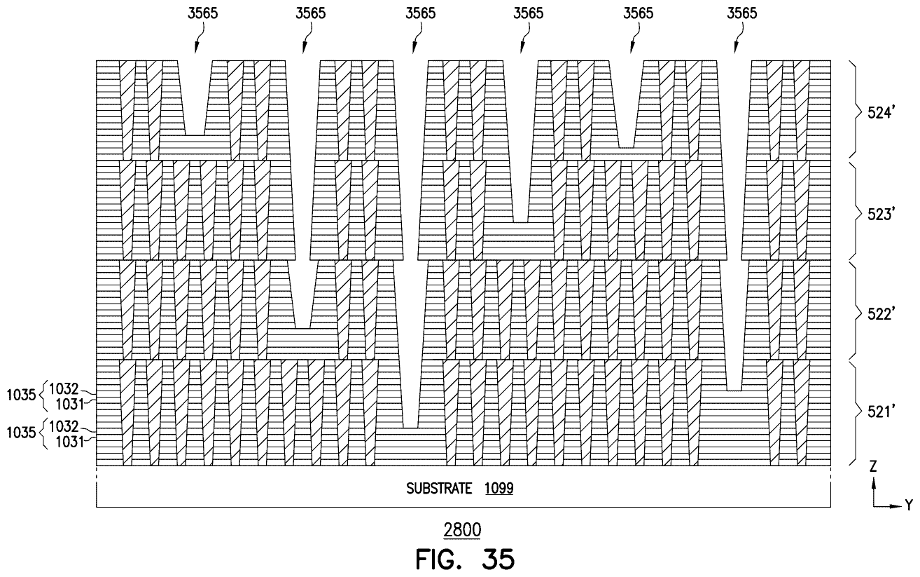

FIG. 35 shows memory device 2800 after the removal (e.g., exhumation) of materials in pillars 3165 (shown in FIG. 34, labeled in FIG. 31) that are under contact openings 3565 in FIG. 35. As shown in FIG. 35, contact openings 3565 are formed through decks 522′, 523′, and 524′ and at least partially through deck 521′. Contact openings 3565 are similar to contact openings 1565 of FIG. 15A.

After the processes associated with FIG. 35 are performed, the processes of forming memory device 2800 can include additional processes to form a complete memory device. For examples, the processes of forming memory device 2800 can continue with processes similar to the processes associated with FIGS. 16A and 16B through FIG. 27A, FIG. 27B, and FIG. 27C to form conductive contacts at contact openings 3565 of memory device 2800 in FIG. 35. The conductive contacts of memory device 2800 can be similar to conductive contacts 665′% and 665′1 memory device 1000 of FIG. 25B through FIG. 27B. For simplicity, the description of the additional processes to form conductive contacts of memory device 2800 are omitted. Improvements and benefits of memory device 2800 are similar to or the same as improvements and benefits of memory device 200 described above.

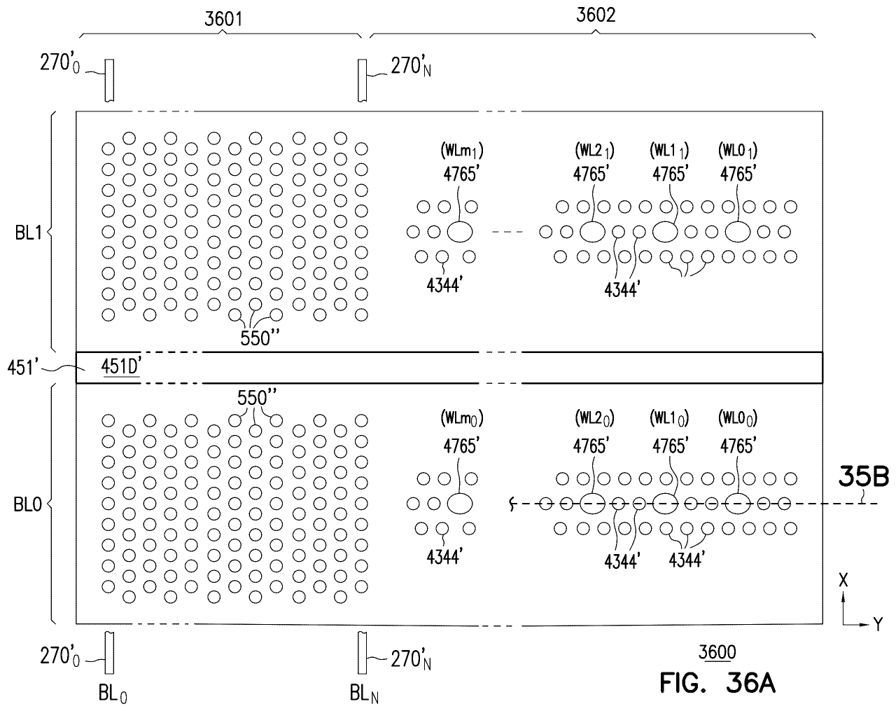

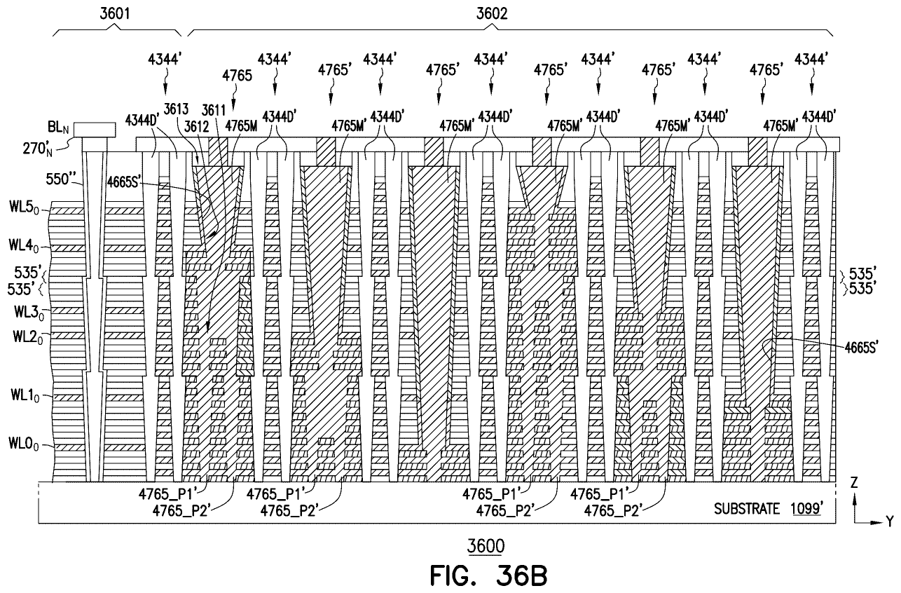

FIG. 36A and FIG. 36B show a top view and a side view, respectively, of a memory device 3600 including conductive contacts 4765′, according to some embodiments described herein. FIG. 36B shows a sideview (e.g., cross-section) of block BLK0 of memory device 3600 at line 36B of FIG. 36A. Memory device 3600 can include elements that are similar to or the same as the elements of memory devices 200, 1000, and 2800. Thus, for simplicity, descriptions of similar or the same elements are not repeated.

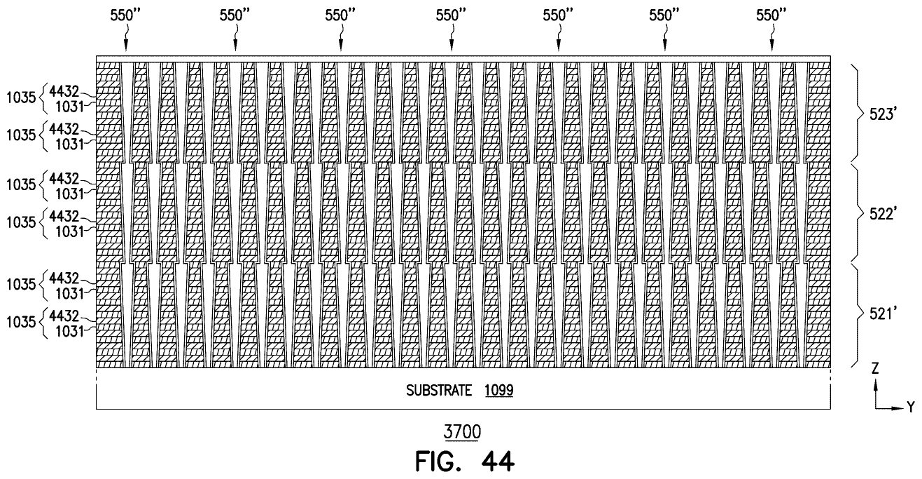

In FIG. 36A and FIG. 36B, pillars (memory cell pillars) 550″ can be similar to pillars 550 of memory device 200 (FIG. 6), memory cell pillars 500′ of memory device 1000 (FIG. 22B), or memory cell pillars 500″ of memory device 3700 (FIG. 44). As shown in FIG. 36A, memory device 3600 can include blocks BLK0 and BLK1, dielectric structure 451′ including a material (e.g., dielectric material) 451D′ between blocks BLK0 and BLK1, and data lines 270′₀ through 270′_{N} associated with signals BL₀ through BL_{N}. Blocks BLK0 and BLK1 and dielectric structure 451′ are similar to BLK0 and BLK1, and dielectric structure 451, respectively, of memory device 1000 of FIG. 6.

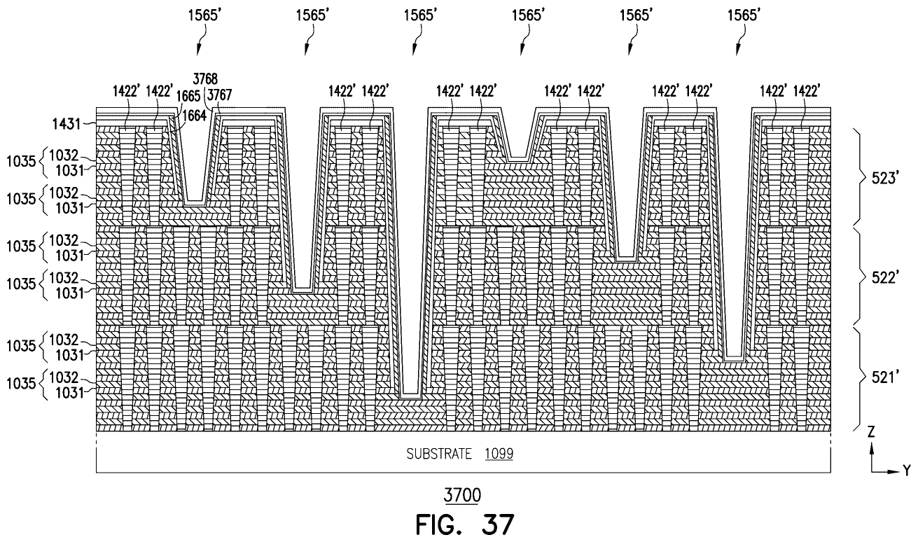

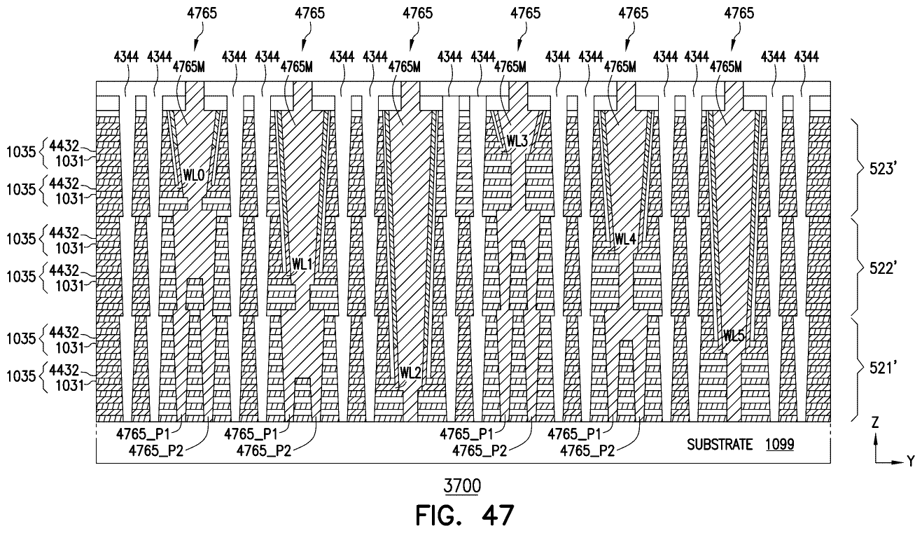

As shown in FIG. 36A and FIG. 36B, memory device 3600 can include a region 3601 and a region 3602. Region 3601 can be called a memory array region where pillars (memory cell pillars) 550″ are located. Region 3602 can be called a contact region where conductive contacts 4765′ are located. Conductive contacts 4765′ can include conductive material 4765M′. Conductive contacts 4765′ and conductive material 4765M′ can be similar to conductive contacts 4765 and conductive material 4765M′, respectively, of memory device 3700 in FIG. 47. Thus, conductive contacts 4765′ of memory device 3600 can be formed by processes similar to the processes of forming conductive contact 4765 in memory device 3700 associated with FIG. 37 through FIG. 47 (described below). In FIG. 36A, block BLK0 can include control gates associated with signals WL0₀ through WLm₀. BLK1 can include control gates associated with signals WL0₁ through WLm₁. As shown in FIG. 36A, conductive contact 4765′ in block BLK0 can be associated with respective control gates (signals WL0₀ through WLm₀).

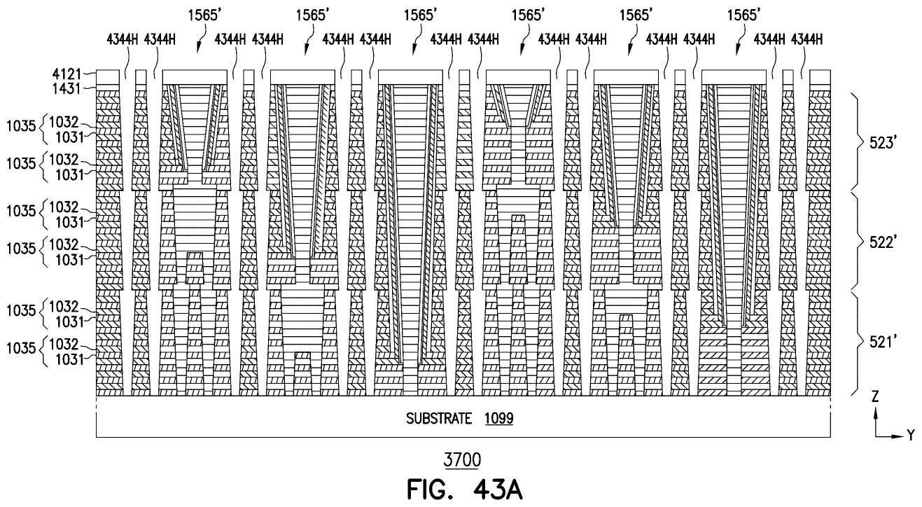

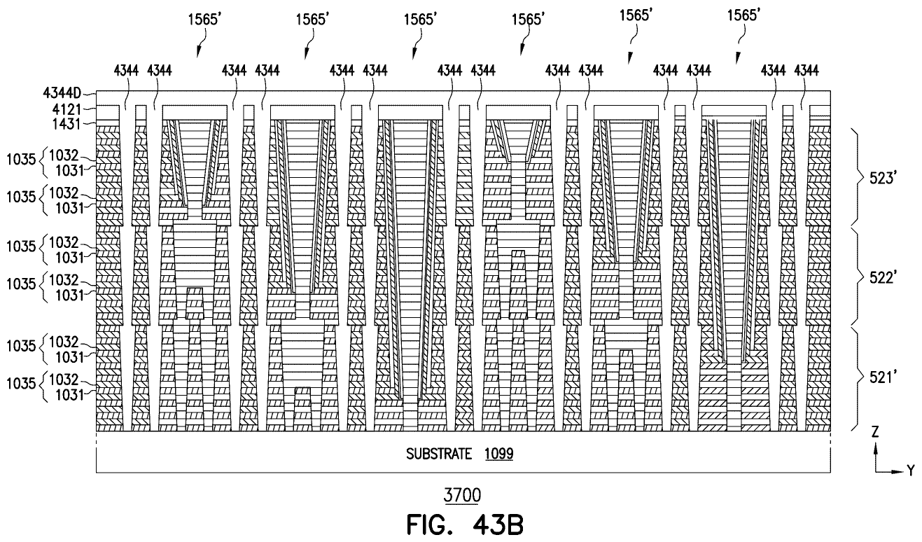

FIG. 36A and FIG. 36B also show support pillars (e.g., dielectric pillars) 4344′ of memory device 3600. Support pillars 4344′ can include a dielectric material (e.g., silicon dioxide) 4344D′. Support pillars 4344′ can be formed to provide structural support for memory device 3600 at region 3602. Support pillars 4344′ can be similar to support pillar 4344 of memory device 3700 of FIG. 43B through FIG. 47. Thus, support pillars 4344′ of memory device 3600 can be formed by processes similar to the processes of forming support pillars 4344 in memory device 3700 associated with FIG. 37 through FIG. 47 (described below).

FIG. 36B shows control gates (associated signals WL0₀, WL1₀, WL2₀, WL3₀, WL4₀, and WL5₀) associated with conductive contacts 4765′ and pillar 550″ (only one pillar 550″ is shown for simplicity). Signals WL0₀, WL1₀, WL2₀, WL3₀, WL4₀, and WL5₀ in FIG. 36B are some of signals WL0₀ through WLm₀ of FIG. 36A. As shown in FIG. 36B, the control gates can be located on respective tiers 535′ (only two tiers 535′ are labeled). The control gates of FIG. 36B are similar to the control gates associated with signals WL0 through WL5 in FIG. 47 of memory device 3700. For simplicity, other control gates (not labeled) in respective tiers of memory device 3600 shown in FIG. 36B are not drawn with cross-sectional lines (e.g., hatch lines).

FIG. 36B shows an example pattern of conductive contacts 4765′ coupling to associated control gates of memory device 3600. However, memory device 3600 can have different patterns, as long as different control gates are associated with (coupled to) different conductive contacts. This means that two different control gates are associated with two different conductive contacts (and are not sharing conductive contacts).

As shown in FIG. 36B, each of conductive contacts 4765′ can include portions 3611, a portion 3612 located over portion in the Z-direction, and a portion 3613 located over a portion 3612 in the Z-direction. At least one (e.g., two or more) of conductive contacts 4765′ includes a portion that includes at least one conductive pillar, such as conductive pillars 4765_P1′ and 4765_P2′. For example, as shown in FIG. 36B, conductive contact 4765 associated with the control gate associated with signal WL4₀ can include portion 3611, which includes conductive pillars 4765_P1′ and 4765_P2′. Conductive pillars 4765_P1′ and 4765_P2′ of portion 3611 are part of respective conductive contacts 4765′ and have the same conductive material 4765M′ as other portions (e.g., portions 3612 and 3613) as conductive contacts 4765′.

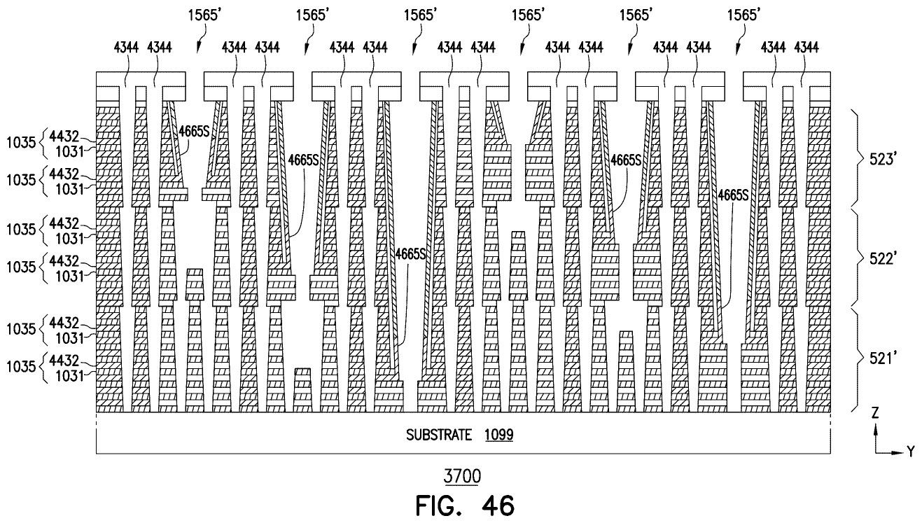

As shown in FIG. 36B, each of conductive contacts 4765′ can include a conductive strap 4665S′. Only two conductive straps 4665S′ are labeled in FIG. 36B for simplicity. Conductive strap 4665S′ is similar to or the same as conductive strap 4665S of memory device 3700 of FIG. 46. As shown in FIG. 36B, in the conductive contact 4765 associated with the control gate associated with signal WL4₀, conductive strap 4665S′ can be part of (e.g., can be located at) portion 3612 and contacting the control gate associated with signal WL4₀. Thus, as shown in FIG. 36B, conductive contact 4765′ associated with the control gate associated with signal WL4₀ can contact the control gate associated with signal WL4₀ at portion 3612, which is between portion 3611 and portion 3613.

FIG. 36B shows portion 3611 of a respective conductive contact 4765′ including two conductive pillars 4765_P1′ and 4765_P2′ in portion 3611 as an example. However, in an alternative structure of memory device 3600, the number pillars (like conductive pillars 4765_P1′ and 4765_P2′) can vary.

In another alternative structure of memory device 3600, portion 3611 can have a structure different from the structure (e.g., different from the pillar structures) shown in FIG. 36B. For example, portion 3611 may include a piece of material (e.g., either conductive or non-conductive material) without a pillar structure like the pillar structure of pillars 4765_P1′ and 4765_P2′.

In FIG. 36B, portions 3611, 3612, and 3613 have the same conductive material (e.g., conductive material 4765M′) as an example. However, in an alternative structure of memory device 3600, portion 3611 can be a dielectric portion such that portion 3611 can include a material (e.g., a non-conductive material (e.g., dielectric material)) that is different from conductive material 4765M. For example, portion 3611 can include a dielectric pillar (or dielectric pillars).

Conductive contacts 4765′ and support pillars 4344′ can provide structural support for part of memory device 3600 to prevent damage to memory device 3600 during processes of forming memory device 3600. For example, tiers 535′ in region 3602 (FIG. 36B) of memory device 3600 can be susceptible to collapse (e.g., tier collapse), bending (e.g., tier bending) or both during processes of forming memory device 3600. Conductive contacts 4765′ and support pillars 4344′ can provide structural support to prevent such collapse or bending. Memory device 3600 also have other improvements and benefits similar to those of memory device 200 and 1000 described above.

The above description with reference to FIGS. 36A and 36B describes the structure of memory device 3600. Some or all of the structure of memory device 200 can be formed using processes associated with the processes described below with reference to FIG. 10A through FIG. 27C and FIG. 37 through FIG. 47

FIG. 37 through FIG. 47 show different views of elements during alternative processes of forming a memory device 3700, according to some embodiments described herein. Some of the processes and materials used in forming memory device 3700 are similar to or the same as the processes of forming memory device 1000. Thus, for simplicity, detailed description of similar or the same process and materials are not repeated. Also, for simplicity, cross-sectional lines (e.g., hatch lines) are omitted from some or all the elements shown in FIG. 27 through FIG. 47.

FIG. 37 shows memory device 3700 after some of the elements of memory device 3700 formed. The elements of memory device 3700 in FIG. 37 are similar to those of memory device 1000 shown in FIG. 16A. For example, contact openings (e.g., holes) 1565′ are similar to contact openings 1565 in FIG. 15. Spacers 1664 and 1665 are similar to or the same as spacers 1664 and 1665 of FIG. 16. Pillars 1422′ are similar to pillars 1422 of FIG. 14A. Thus, the processes associated with FIG. 10A through FIG. 16A can be used to form memory device 3700 in FIG. 37.

FIG. 37 shows memory device 3700 after spacers (dielectric spacers) 3767 and 3768 are formed in addition to spacers 1664 and 1665. Spacer 3767 can be formed from silicon dioxide or other materials that can protect spacer from being removed (e.g., exhumed) from subsequent processes (e.g., in FIG. 44). An example material for spacer 3767 include polysilicon.

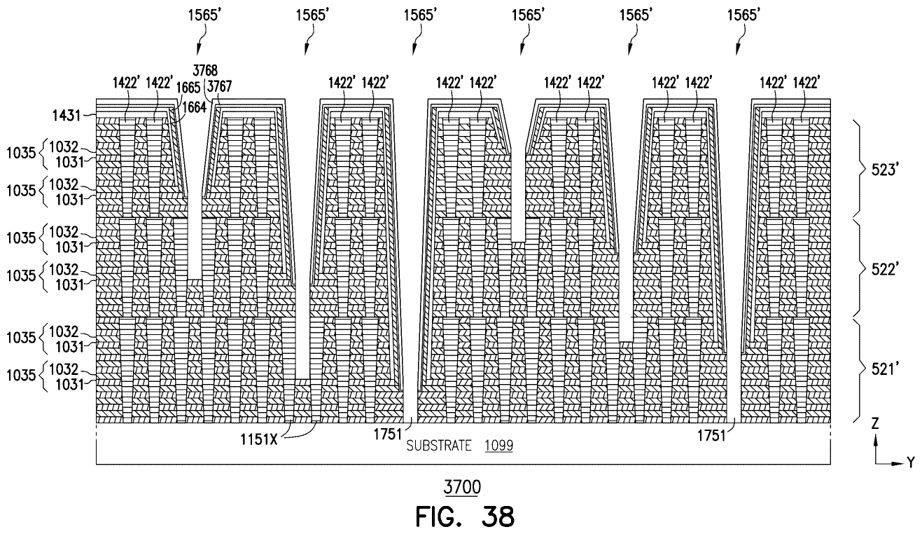

FIG. 38 shows memory device 3700 after a portion of material directly under contact openings 1565′ is removed to form cuts 1751 (only two are labeled) under respective contact openings 1565′. Cuts (e.g., open spaces) 1751 can be formed to expose deepest openings (e.g., openings 1151X) that were filled with sacrificial material 1233 in FIG. 12A.

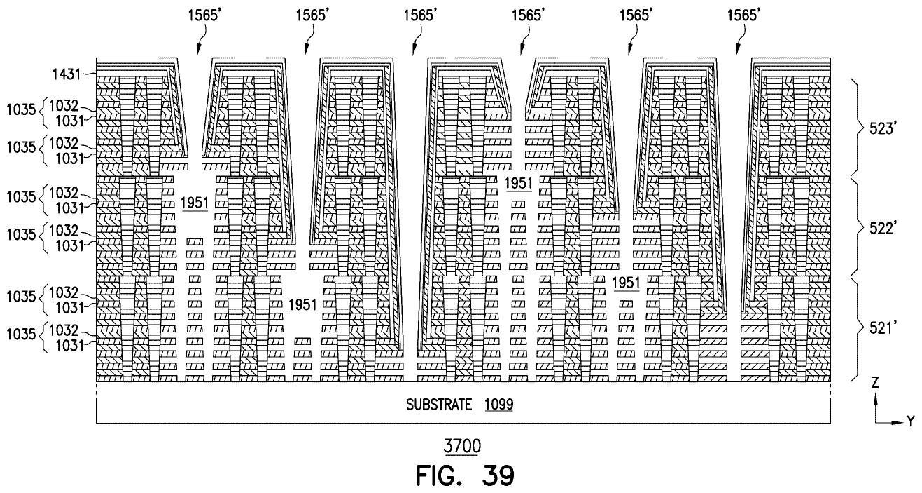

FIG. 39 shows memory device 3700 after open spaces 1951 are formed. Forming open spaces 1951 can include removing (exhuming) the material at open spaces 1951 to expose dielectric materials 1032 (e.g., silicon nitride of tiers 1035) at open spaces 1951. The material removed from open spaces 1951 can be similar to sacrificial materials 1233 and 1333 formed in FIG. 12A and FIG. 13A, respectively. In FIG. 39, dielectric materials 1032 (that are exposed) at open spaces 1951 also can be removed (e.g., etched).

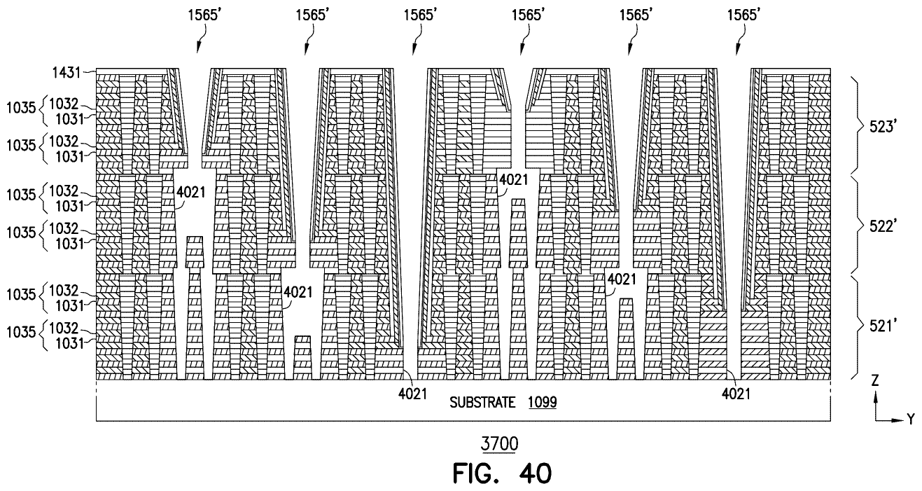

FIG. 40 shows memory device 3700 after a dielectric material (silicon dioxide) 4021 is formed in respective open space 1951 in the locations of dielectric materials 1032 that were removed in FIG. 39.

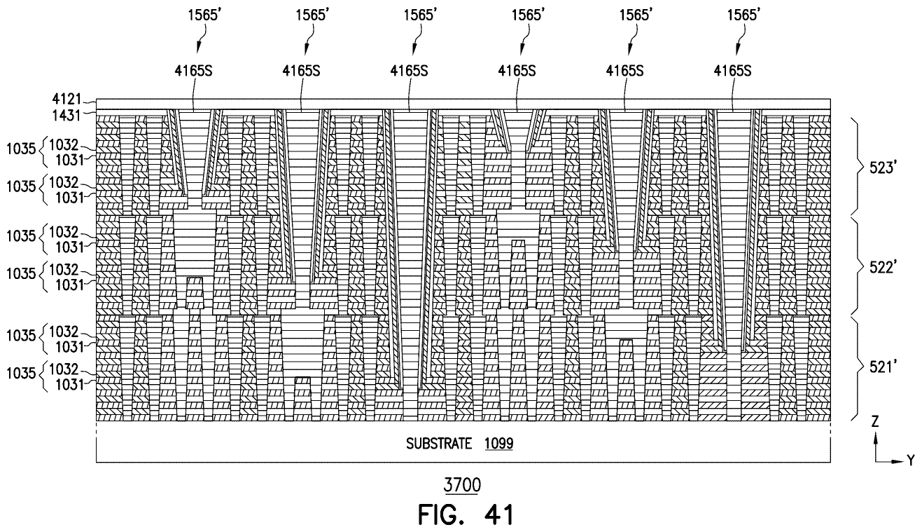

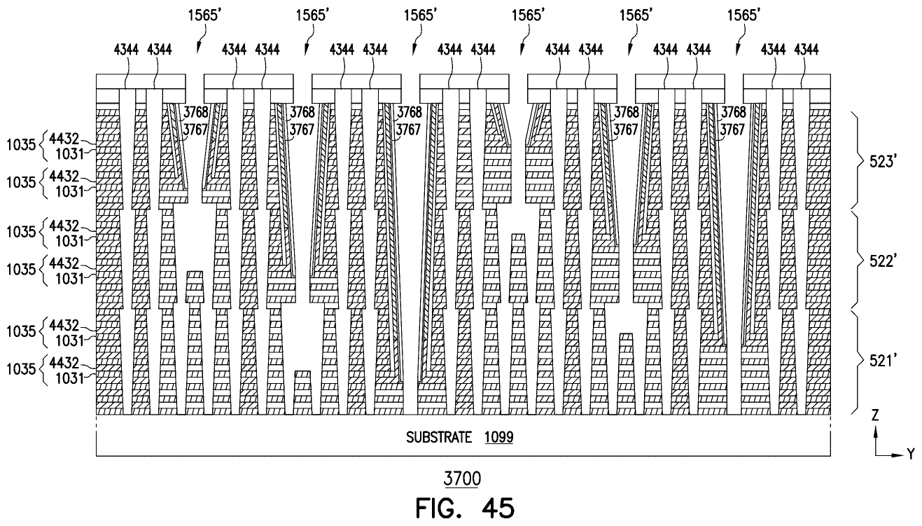

FIG. 41 shows memory device 3700 after a material (e.g., carbon or polysilicon) 4165S is formed in respective contact opening 1565′. Material 4165S is a sacrificial material that will be removed in subsequent processes (in FIG. 45). A material (e.g., silicon dioxide) 4121 can also be formed over other materials as shown in FIG. 41.

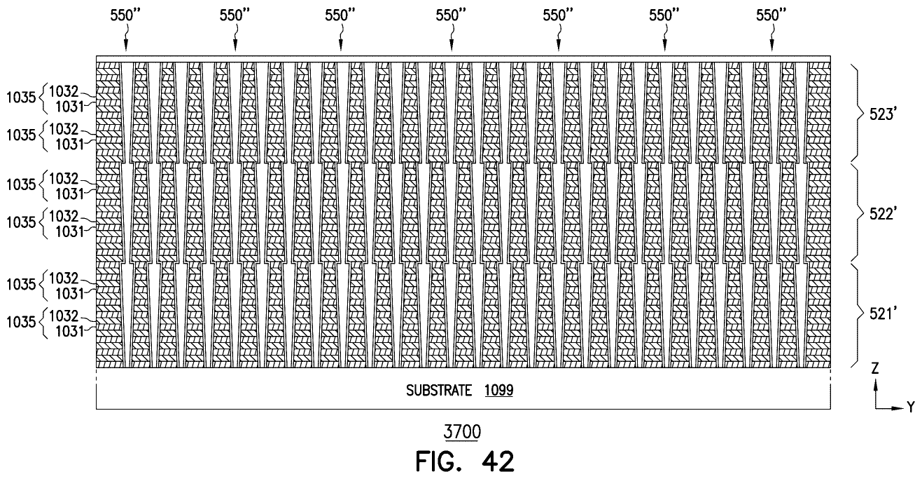

FIG. 42 shows memory device 3700 after memory cells (not labeled) and associated pillars 550″ are formed. The locations of pillars 550″ can be similar to the locations of pillars 550″ at region 3601 of memory device 3600 of FIG. 36A and FIG. 36B.

FIG. 43A shows memory device 3700 after openings 4344H are formed in the location of pillars 1422 (labeled in FIG. 38). Forming openings 4344H can include patterning and removing the materials from respective pillars 1422. The materials that were removed materials from respective pillars (FIG. 37) can be similar to materials 1233, 1333, and 1433 in FIG. 14.

FIG. 43B shows memory device 3700 after support pillars 4344 are formed in the locations of openings 4344H (labeled in FIG. 43A). Forming pillars 4344 can include forming (e.g., filling) a material (e.g., silicon dioxide) 4344D in openings 4344H. Support pillars 4344 can be formed to provide structural support for memory device 3700 at the region of memory device 3700 (e.g., like region 3602 in FIG. 36B) at which conductive contacts 4765 of memory device 3700 are located.

FIG. 44 shows memory device 3700 after conductive material (or conductive materials) 4432 are formed in tiers 1035. Forming conductive material 4432 can include removing (e.g., exhuming) dielectric materials (e.g., silicon nitride) 1032 in tiers 1035. Then, conductive material 4432 can be formed in the locations of dielectric materials 1032 that were removed. Conductive material 4432 can be similar to or the same as conductive material 532 of FIG. 9A. Conductive material 4432 in respective tiers 1035 can form respective control gates of memory device 3700, such as the control gates associated with signals WL0, WL1, WL2, WL3, WL4, and WL5 in FIG. 47 of memory device 3700.

FIG. 45 shows memory device 3700 after material (sacrificial material) 4165S (formed in FIG. 41) is removed from contact openings 1565′. A patterning and etch process can be used to remove material 4165S from contact openings 1565′. The processes associated with FIG. 45 can expose spacer 3768 at respective contact openings 1565′.

FIG. 46 shows memory device 3700 after spacers 3767 and 3768 are removed from contact openings 1565′. A patterning and etch process can be used to remove spacers 3767 and 3768. As shown in FIG. 46, memory device 3700 can include a conductive strap 4665S that can be formed from conductive material 4432 during the processes of forming the control gates of memory device 3700 in FIG. 44. For example, like dielectric materials 1032 in tiers 1035 in FIG. 44 that were replaced by conductive material 4432 in FIG. 44, a portion of spacer 1665 (labeled in FIG. 37) was also removed and replaced by conductive material 4432. Conductive strap 4665S can be part of a respective conductive contact 4765 (FIG. 47) formed in a respective contact opening 1565′.

FIG. 47 shows memory device 3700 after conductive contacts 4765 are formed at the locations of contact openings 1565′ (labeled in FIG. 46). Forming conductive contacts 4765 can include forming (e.g., filing) a conductive material (e.g., metal or a combination of different conductive materials) 4765M in contact openings 1565′

As shown in FIG. 47, conductive contacts 4765 can contact respective control gates (associated with signals WL0, WL1, WL2, WL3, WL4, and WL5). FIG. 47 shows a portion of memory device 3700 including six control gates (associated with six signals WL0 through WL5) for simplicity. Memory device 3700 can include numerous control gates. The control gates associated with signal WL0 through WL5 can represent the control gates associated with signal WL0₀, WL1₀, WL2₀, WL3₀, WL4₀, and WL5₀, respectively, of memory device 3600 of FIG. 36B.

FIG. 47 shows an example structure of conductive contacts 4765. However, conductive contacts 4765 can have different structures and materials (e.g., variations) similar to those of portions 3611, 3612, and 3613 of conductive contacts 4765′ of memory device 3600 of FIG. 36B.

The processes of forming memory device 3700 described above with reference to FIG. 37 through FIG. 47 can include other processes to form a complete memory device. Such processes are omitted from the above description so as not to obscure the subject matter described herein. Improvements and benefits of memory device 3700 are similar to or the same as improvements and benefits of memory device 200 described above.

The illustrations of apparatuses (e.g., memory devices 100, 200, 1000, 2800, 3600, and 3700) and methods (e.g., method of forming memory devices 1000 and 2600) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 1000, 2800, 3600, and 3700) or a system (e.g., a computer, a cellular phone, or other electronic systems) that includes a device such as any of memory devices 100, 200, 1000, 2800, 3600, and 3700.

Any of the components described above with reference to FIG. 1 through FIG. 47 can be implemented in a number of ways, including simulation via software. Thus, apparatuses, e.g., memory devices 100, 200, 1000, 2800, 3600, and 3700, or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 1000, 2800, 3600, and 3700 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 47 include apparatuses and methods of forming the apparatuses. One of the apparatuses includes a memory device, which includes: a first region including first levels of conductive materials interleaved with first levels of dielectric materials, and first memory cells including pillars extending through at least a portion of the first levels of conductive materials and first levels of dielectric materials; a second region including second levels of conductive materials interleaved with second levels of dielectric materials, and second memory cells including pillars extending through at least a portion of the first levels of conductive materials and first levels of dielectric materials; a third region including a dielectric structure separating the first levels of conductive materials from the second levels of conductive materials; and a conductive contact extending through at least a portion of the third region and contacting a conductive material of the first levels of conductive materials. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first region including first levels of conductive materials interleaved with first levels of dielectric materials, and first memory cells including pillars extending through at least a portion of the first levels of conductive materials and first levels of dielectric materials;
a second region including second levels of conductive materials interleaved with second levels of dielectric materials, and second memory cells including pillars extending through at least a portion of the first levels of conductive materials and first levels of dielectric materials;
a third region including a dielectric structure separating the first levels of conductive materials from the second levels of conductive materials; and
a conductive contact extending through at least a portion of the third region and contacting a conductive material of the first levels of conductive materials.

2. The apparatus of claim 1, wherein the dielectric structure includes a dielectric portion, the dielectric portion includes a side wall, and the conductive contact wraps a portion of the side wall of the dielectric portion.

3. The apparatus of claim 1, further comprising an additional conductive contact extending through at least a portion of the third region and contacting a conductive material of the second levels of conductive materials.

4. The apparatus of claim 3, wherein:
the dielectric structure includes a dielectric portion, the dielectric portion includes a side wall;
the conductive contact is adjacent a first portion of the side wall of the dielectric portion; and
the additional conductive contact is adjacent a second portion of the side wall of the dielectric portion.

5. The apparatus of claim 3, wherein the dielectric structure includes a length in a direction perpendicular to a direction from the conductive contact to the additional conductive contact.

6. The apparatus of claim 3, wherein the conductive contact and the additional conductive contact have a same length.

7. The apparatus of claim 3, wherein the conductive material of the first levels of conductive materials and the conductive material of the second levels of conductive materials are located on a same level of the apparatus.

8. The apparatus of claim 1, wherein the first levels of conductive materials form first control gates associated with the first memory cells, and the second levels of conductive materials form second control gates associated with the second memory cells.

9. The apparatus of claim 1, wherein the apparatus comprises a memory device, the memory device including a first memory cell block and a second memory cell block, wherein the first memory cells are included in the first memory cell block, and the second memory cells are included in the second memory cell block.

10. An apparatus comprising:
first levels of conductive materials interleaved with first levels of dielectric materials;
second levels of conductive materials interleaved with second levels of dielectric materials, the second levels of conductive materials and the second levels of dielectric materials located over the first levels of conductive materials and the first levels of dielectric materials;
memory cells including pillars associated with the memory cells, the pillars extending through the first levels of conductive materials, the first levels of dielectric materials, the second levels of conductive materials, and the second levels of dielectric materials; and
a conductive contact extending in a direction from the second levels of conductive materials to the first levels of conductive materials, the conductive contact including a first conductive portion, a third conductive portion, and a second conductive portion between the first portion and the third portion, wherein the second conductive portion contacts one of the second levels of conductive materials.

11. The apparatus of claim 10, wherein the first conductive portion includes a conductive pillar.

12. The apparatus of claim 11, wherein the first conductive portion includes an additional conductive pillar.

13. The apparatus of claim 10, further comprising an additional conductive contact extending in the direction from the second levels of conductive materials to the first levels of conductive materials, the additional conductive contact including a fourth conductive portion, a sixth conductive portion, and a fifth conductive portion between the fourth portion and the sixth portion wherein the fifth conductive portion contacts one of the second levels of conductive materials.

14. The apparatus of claim 13, wherein the fourth conductive portion of the additional conductive contact includes at least one conductive pillar.

15. The apparatus of claim 10, further comprising a dielectric pillar adjacent the conductive contact and extending through the first levels of conductive materials, the first levels of dielectric materials, the second levels of conductive materials, and the second levels of dielectric materials.

16. The apparatus of claim 15, further comprising an additional dielectric pillar, wherein the dielectric pillar is between the additional dielectric pillar and the conductive contact.

17. The apparatus of claim 10, wherein the first levels of conductive materials form first control gates associated with the memory cells, and the second levels of conductive materials form second control gates associated with the memory cells.

18. A method comprising:
forming first memory cells and first control gates associated with the first memory cells;
forming second memory cells and second control gates associated with the second memory cells;
forming a dielectric structure between the first memory cells and the second memory cells;
forming a first conductive contact through a first portion of the dielectric structure and contacting a first control gate of the first control gates; and
forming a second conductive contact through a second portion of the dielectric structure and contacting a second control gate of the second control gates.

19. The method of claim 18, wherein forming the first conductive contact includes:
forming a conductive material at a first location and a second location, wherein a first portion of the conductive material forms the first conductive contact, and a second portion of the conductive material forms the first control gate.

20. The method of claim 18, wherein forming the first conductive contact and the second conductive contact includes:
forming a conductive material in an opening; and
removing a part of the conductive material to obtain a first remaining portion of the conductive material and a second remaining portion of the conductive material, wherein the first remaining portion of the conductive material forms the first conductive contact, and the second remaining portion of the conductive material forms the second conductive contact.
